(19) United States
(12) Patent Application Publication
(10) Pub. No.: US 2025/0104964 A1
(43) Pub. Date: Mar. 27, 2025

(54) METHOD FOR CALCULATING EFFECTIVE TEMPERATURE OF MULTI-CHARGED PARTICLE BEAM WRITING REGION, MULTI-CHARGED PARTICLE BEAM WRITING METHOD, NON-TRANSITORY COMPUTER-READABLE STORAGE MEDIUM STORING A PROGRAM, AND MULTI-CHARGED PARTICLE BEAM WRITING APPARATUS

(71) Applicant: NuFlare Technology, Inc., Yokohama-shi (JP)

(72) Inventors: Haruyuki NOMURA, Yokohama-shi (JP); Shingo MORI, Yokohama-shi (JP)

(73) Assignee: NuFlare Technology, Inc., Yokohama-shi (JP)

(21) Appl. No.: 18/904,069

(22) Filed: Oct. 1, 2024

Related U.S. Application Data
(63) Continuation of application No. PCT/JP2023/034349, filed on Sep. 21, 2023.

(51) Int. Cl. H01J 37/304; H01J 37/317

(52) U.S. Cl. CPC H01J 37/304; H01J 37/3174; H01J 2237/24585

(57) ABSTRACT

Method for calculating an effective temperature of a multi-charged-particle-beam writing region includes calculating a representative value of a dose of a beam to be applied to a mesh region concerned, as a dose representative value, for each of plural mesh regions obtained by dividing, in a writing direction and a linearly independent first direction to the writing direction, a writing region of a target object to be irradiated with multiple-charged-particle-beams; and calculating, as an effective temperature of each of the plural mesh regions, a representative value of an increased temperature given to each of the plural mesh regions by heat due to beam irradiation, by performing convolution processing between the dose representative value and a kernel determined by a speed of a stage with the target object thereon, and a size in the writing direction of a beam array region of the multiple-charged-particle-beams on the surface of the target object.

### CROSS-REFERENCE TO RELATED APPLICATION

This application is a continuation application based upon and claims the benefit of priority from International Application PCT/JP2023/034349, the International Filing Date of which is Sep. 21, 2023. The contents described in PCT/JP2023/034349 are incorporated herein by reference.

### BACKGROUND OF THE INVENTION

### Field of the Invention

Embodiments of the present invention relate to a calculation method for effective temperature in multi-charged particle beam writing region, a multi-charged particle beam writing apparatus, a multi-charged particle beam writing method, and a program (or a computer-readable storage medium storing non-transitory programs). For example, they relate to a correction method for resist heating occurring in multi-beam writing.

### Description of Related Art

The lithography technique which advances miniaturization of semiconductor devices is extremely important as a unique process whereby patterns are formed in semiconductor manufacturing. In recent years, with high integration of LSI, the line width (critical dimension) required for semiconductor device circuits is becoming increasingly finer year by year. The electron beam writing technique, which intrinsically has excellent resolution, is used for writing or “drawing” on a wafer and the like with electron beams.

For example, as a known example of employing the electron beam writing technique, there is a writing apparatus using multiple beams. Since it is possible for multi-beam (multiple beam) writing to apply multiple beams at a time, the writing throughput can be greatly increased in comparison with single electron beam writing. For example, a writing apparatus employing the multiple beam system forms multiple beams by letting an electron beam emitted from an electron gun pass through a mask having a plurality of holes, performs blanking control for each beam, reduces each unblocked beam by an optical system, and deflects it by a deflector to irradiate a desired position on a target object or “sample”.

In electron beam writing, if trying to apply an irradiation energy amount in a short time by using high-density electron beams, a problem occurs in that the substrate overheats resulting in a phenomenon called “resist heating” of changing the resist sensitivity and degrading the line width accuracy (e.g., refer to Japanese Translation of PCT International Application Publication No. 2003-503837). For example, in single beam writing, a method has been performed in which a dose correction amount of a current shot is determined by accumulating the influence of temperature increase of each previous shot of one beam. In contrast, however, in multiple beam writing, since a plurality of beams are used, if the method of accumulating the influence of temperature increase of each previous shot per beam is employed, the calculation amount becomes huge. Further, in multiple beam writing, since a plurality of beams are shot simultaneously, it is necessary to take into consideration the temperature increase influence from a plurality of other beams located in the wide region irradiated at the same time.

### BRIEF SUMMARY OF THE INVENTION

According to one aspect of the present invention, a method for calculating an effective temperature of a multi-charged particle beam writing region, includes calculating a representative value of a dose of a beam to be applied to a mesh region concerned, as a dose representative value, for each of a plurality of mesh regions obtained by dividing, in a writing direction and a linearly independent first direction to the writing direction, a writing region of a target object to be irradiated with multiple charged particle beams; and calculating, as an effective temperature of the each of the plurality of mesh regions, a representative value of an increased temperature given to the each of the plurality of mesh regions by heat due to beam irradiation, by performing convolution processing between the dose representative value and a kernel determined according to a speed of a stage with the target object thereon, and a size in the writing direction of a beam array region of the multiple charged particle beams on a surface of the target object, and outputting the effective temperature.

According to another aspect of the present invention, a multi-charged particle beam writing method includes
calculating, using an effective temperature obtained by the method descried above of each of the plurality of mesh regions, a correction amount to correct one of a dose of a plurality of beams, to be applied to a target mesh region being one of the plurality of mesh regions, of multiple charged particle beams, and pattern data of a figure to be written in the target mesh region; and
writing, with the multiple charged particle beams, a pattern on a target object by using the correction amount.

According to yet another aspect of the present invention, a non-transitory computer-readable storage medium storing a program for causing a computer to execute processing includes
calculating a representative value of a dose of a beam to be applied to a mesh region concerned, as a dose representative value, for each of a plurality of mesh regions obtained by dividing, in a writing direction and a linearly independent first direction to the writing direction, a writing region of a target object to be irradiated with multiple charged particle beams; and
calculating, as an effective temperature of the each of the plurality of mesh regions, a representative value of an increased temperature given to the each of the plurality of mesh regions by heat due to beam irradiation, by performing convolution processing between the dose representative value and a kernel determined according to a speed of a stage with the target object thereon, and a size in the writing direction of the beam array region of the multiple charged particle beams on a surface of the target object, and outputting the effective temperature.

According to yet another aspect of the present invention, a non-transitory computer-readable storage medium storing a program for causing a computer to execute processing, includes
calculating the dose representative value and calculating the effective temperature value described above;
calculating, using an effective temperature of each of the plurality of mesh regions, a correction amount to correct one of a dose of a plurality of beams, to be applied to a target mesh region being one of the plurality of mesh regions, of multiple charged particle beams, and pattern data of a figure to be written in the target mesh region; and
writing, with the multiple charged particle beams, a pattern on a target object by using the correction amount.

According to yet another aspect of the present invention, a multi-charged particle beam writing apparatus includes
a dose representative value calculation circuit configured to calculate a representative value of a dose of a beam to be applied to a mesh region concerned, as a dose representative value, for each of a plurality of mesh regions obtained by dividing, in a writing direction and a linearly independent first direction to the writing direction, a writing region of a target object to be irradiated with multiple charged particle beams;
an effective temperature calculation circuit configured to calculate, as an effective temperature of the each of the plurality of mesh regions, a representative value of an increased temperature given to the each of the plurality of mesh regions by heat due to beam irradiation, by performing convolution processing between the dose representative value and a kernel determined according to a speed of a stage with the target object thereon, and a size in the writing direction of the beam array region of the multiple charged particle beams on a surface of the target object;
a correction amount calculation circuit configured to calculate, using an effective temperature of the each of the plurality of mesh regions, a correction amount to correct one of a dose of a plurality of beams, to be applied to a target mesh region being one of the plurality of mesh regions, of the multiple charged particle beams, and pattern data of a figure to be written in the target mesh region; and
a writing mechanism configured to write, with the multiple charged particle beams, a pattern on the target object by using the correction amount.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a top view conceptual diagram showing a portion of the structure in a membrane region of a blanking aperture array mechanism according to the first embodiment;

FIG. 5 is a circuit diagram showing an example of an individual blanking mechanism according to the first embodiment;

FIG. 6 is a conceptual diagram illustrating an example of a writing operation according to the first embodiment;

FIG. 7 is an illustration showing an example of an irradiation region of multiple beams and a writing target pixel according to the first embodiment;

FIG. 8 is an illustration explaining an example of a multi-beam writing operation according to the first embodiment;

FIG. 9 is a graph showing an example of a relationship between a temperature distribution and a temperature resulting from applying one beam irradiation to a region of one beam pitch according to a comparative example of the first embodiment;

FIG. 10 is a graph showing an example of a relationship between a temperature distribution and a temperature resulting from applying a simultaneous multiple beam irradiation according to the first embodiment;

FIG. 11 is a flowchart showing an example of main steps of a writing method according to the first embodiment;

FIG. 12 is an illustration showing an example of a processing mesh according to the first embodiment;

FIG. 13 is an illustration explaining a method of calculating an effective temperature according to the first embodiment;

FIG. 14 is an illustration explaining a portion of an equation for calculating an effective temperature according to the first embodiment;

FIG. 15 is an illustration explaining an example of an equation of a heat diffusion function according to the first embodiment;

FIG. 16 is an illustration showing another portion of the equation for calculating an effective temperature according to the first embodiment;

FIG. 17 is an illustration showing another portion of the equation for calculating an effective temperature according to the first embodiment;

FIG. 18 is also an illustration showing another portion of the equation for calculating an effective temperature according to the first embodiment;

FIG. 19 is an illustration showing an example of a virtual model of an effective temperature according to the first embodiment;

FIG. 20 is an illustration showing an example of a kernel derivation process according to the first embodiment;

FIG. 21 is an illustration showing another example of a kernel derivation process according to the first embodiment;

FIG. 22 is an illustration showing another example of a kernel derivation process according to the first embodiment;

FIG. 23 is an illustration explaining a kernel according to the first embodiment;

FIG. 24 is an illustration showing an example of a relationship between a stage speed and a kernel according to the first embodiment;

FIG. 25 is an illustration showing an example of a relationship between a moving direction size of a beam array and a kernel according to the first embodiment;

FIG. 26 is an illustration showing another example of a relationship between a moving direction size of a beam array and a kernel according to the first embodiment;

FIG. 27 is an illustration showing an example of a kernel defined as a table according to the first embodiment;

FIG. 28 is an equation representing an example of a kernel defined as a continuous function according to the first embodiment;

FIG. 29 is an illustration explaining a method of calculating an effective temperature according to the first embodiment;

FIG. 30 is an illustration showing an example of a relationship between a line width CD and a temperature according to the first embodiment;

FIG. 31 is an illustration showing an example of a relationship between a line width CD and a dose according to the first embodiment;

FIG. 32 is an illustration showing an example of a configuration of a writing apparatus according to a second embodiment; and

FIG. 33 is a flowchart showing an example of main steps of a writing method according to the second embodiment.

### DETAILED DESCRIPTION OF THE INVENTION

Embodiments below provide an apparatus and method which can, in multiple beam writing, correct resist heating without accumulating the influence of temperature increase per shot per beam.

Embodiments below describe a configuration in which an electron beam is used as an example of a charged particle beam. The charged particle beam is not limited to the electron beam, and other charged particle beam such as an ion beam may also be used.

### First Embodiment

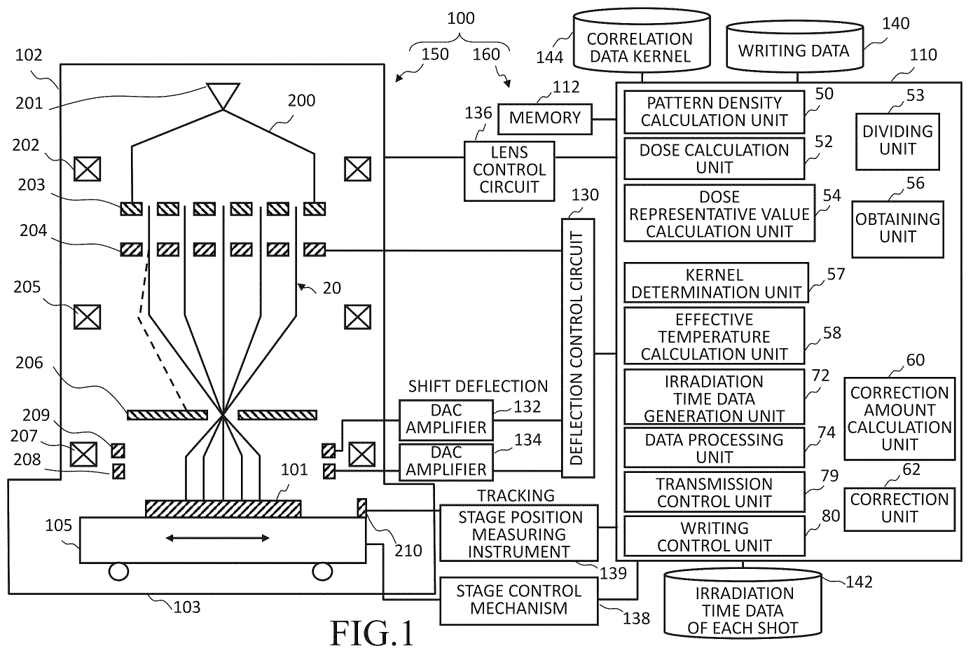

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, and a sub deflector 209. In the writing chamber 103, an XY stage 105 is disposed. On the XY stage 105, there is placed a target object or “sample” 101 such as a mask serving as a writing target substrate when writing (exposure) is performed. The target object 101 is, for example, an exposure mask used when fabricating semiconductor devices, or a semiconductor substrate (silicon wafer) for fabricating semiconductor devices. Resist has been applied to the target object 101. The target object 101 may be, for example, a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140, 142, and 144 such as magnetic disk drives. The control computer 110, the memory 112, the deflection control circuit 130, the lens control circuit 136, the stage control mechanism 138, the stage position measuring instrument 139, and the storage devices 140, 142, and 144 are connected to each other through a bus (not shown). The DAC amplifier unit 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Based on the principle of laser interferometry, the stage position measuring instrument 139 measures the position of the XY stage 105 by receiving a reflected light from the mirror 210.

In the control computer 110, there are arranged a pattern density calculation unit 50, a dose calculation unit 52, a dividing unit 53, a dose representative value calculation unit 54, an obtaining unit 56, a kernel determination unit 57, an effective temperature calculation unit 58, a correction amount calculation unit 60, a correction unit 62, an irradiation time data generation unit 72, a data processing unit 74, a transmission control unit 79, and a writing control unit 80. Each of the “ . . . units” such as the pattern density calculation unit 50, the dose calculation unit 52, the dividing unit 53, the dose representative value calculation unit 54, the obtaining unit 56, the kernel determination unit 57, the effective temperature calculation unit 58, the correction amount calculation unit 60, the correction unit 62, the irradiation time data generation unit 72, the data processing unit 74, the transmission control unit 79, and the writing control unit 80 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the pattern density calculation unit 50, the dose calculation unit 52, the dividing unit 53, the dose representative value calculation unit 54, the obtaining unit 56, the kernel determination unit 57, the effective temperature calculation unit 58, the correction amount calculation unit 60, the correction unit 62, the irradiation time data generation unit 72, the data processing unit 74, the transmission control unit 79, and the writing control unit 80, and information being operated are stored in the memory 112 each time.

Writing operations of the writing apparatus 100 are controlled by the writing control unit 80. The processing of transmitting irradiation time data of each shot to the deflection control circuit 130 is controlled by the transmission control unit 79.

Chip data is input from the outside of the writing apparatus 100, and stored in the storage device 140. Writing data includes chip data and writing condition data. The chip data defines, for example, a figure code, coordinates, size, etc. of each figure pattern. The writing condition data includes information indicating multiplicity, and a stage speed.

Correlation data for calculating a modulation rate which corrects resist heating, to be described later, is stored in the storage device 144.

FIG. 1 shows a configuration necessary for describing the first embodiment. Other configuration elements generally necessary for the writing apparatus 100 may also be included therein.

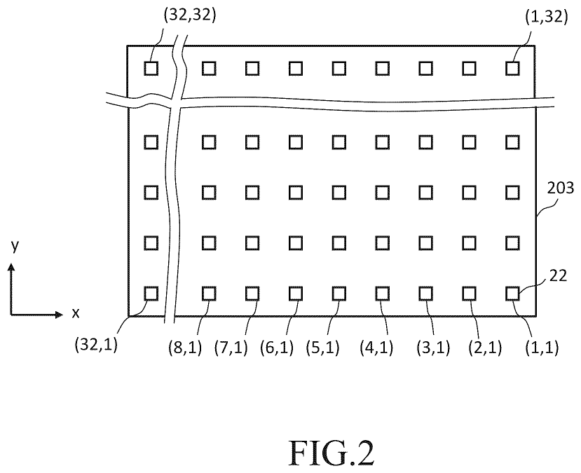

FIG. 2 is a conceptual diagram showing a configuration of a shaping aperture array substrate according to the first embodiment. As shown in FIG. 2, holes (openings, apertures) 22 of p rows long (length in the y direction) and q columns wide (width in x direction) (p≥2, q≥2) are formed, like a matrix, at a predetermined arrangement pitch in the shaping aperture array substrate 203. In FIG. 2, for example, holes 22 of 500 (rows of holes arrayed in the y direction)×500 (columns of holes arrayed in the x direction) are formed. The number of the holes 22 is not limited thereto. Each of the holes 22 is a rectangle, including a square, having the same dimension and shape as each other. Alternatively, each of the holes 22 may be a circle with the same diameter as each other. By making portions of an electron beam 200 individually pass through a corresponding hole of a plurality of holes 22, multiple beams 20 are formed. In other words, the shaping aperture array substrate 203 forms the multiple beams 20.

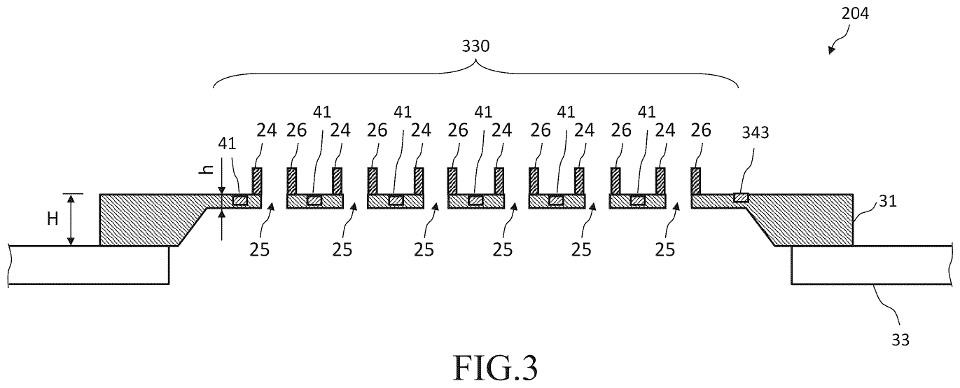

FIG. 3 is a sectional view showing a configuration of a blanking aperture array mechanism according to the first embodiment.

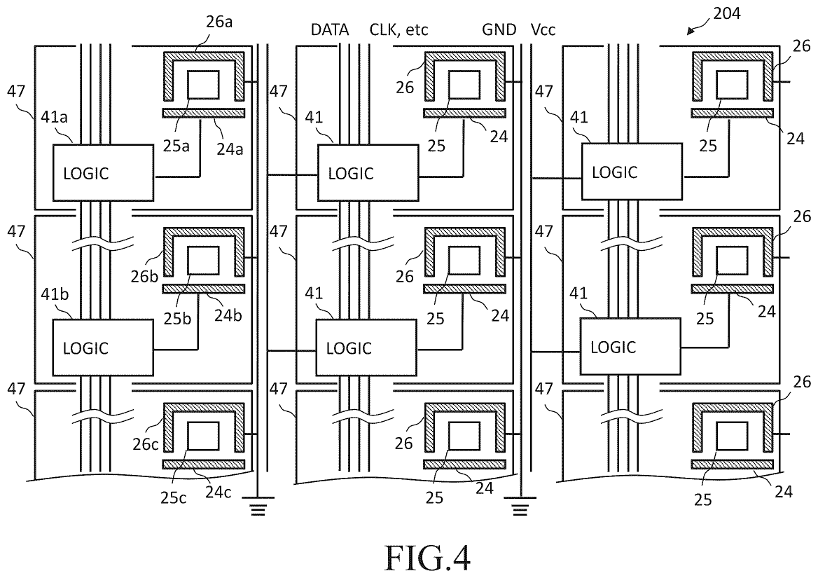

FIG. 4 is a top view conceptual diagram showing a portion of the structure in a membrane region of a blanking aperture array mechanism according to the first embodiment. The position relation of a control electrode 24, a counter electrode 26, a control circuit 41, and a pad 343 in FIG. 3 is not in accordance with that of FIG. 4. With regard to the structure of the blanking aperture array mechanism 204, as shown in FIG. 3, a blanking aperture substrate 31 being a semiconductor substrate made of silicon, etc. is placed on a support table 33. In a membrane region 330 at the center portion of the blanking aperture array substrate 31, passage holes 25 (openings) through each of which a corresponding one of multiple beams 20 passes are formed at positions each corresponding to each hole 22 in the shaping aperture array substrate 203 shown in FIG. 2. A pair of a control electrode 24 and a counter electrode 26, (blanker: blanking deflector) is arranged such that the electrodes 24 and 26 are opposite to each other across each corresponding one of a plurality of passage holes 25. Further, close to each passage hole 25 and inside the blanking aperture array substrate 31, there is arranged the control circuit 41 (logic circuit; cell) which applies a deflection voltage to the control electrode 24 for each passage hole 25 concerned. The counter electrode 26 for each beam is grounded.

As shown in FIG. 4, n-bit (e.g., 10-bit) parallel lines for control signals are connected to each control circuit 41. In addition to the n-bit parallel lines for irradiation time control signals (data), lines for a clock signal, a load signal, a shot signal, a power supply, and the like are connected to each control circuit 41. Alternatively, a part of the parallel lines may be used as these lines. An individual blanking mechanism 47 composed of the control electrode 24, the counter electrode 26, and the control circuit 41 is configured for each beam of the multiple beams 20. In the first embodiment, the shift register method is employed as a data transmission method. According to the shift register method, the multiple beams 20 are divided into a plurality of groups each composed of a plurality of beams, and a plurality of shift registers for a plurality of beams in the same group are connected in series. Specifically, a plurality of control circuits 41 formed in an array in the membrane region 330 are grouped by a predetermined pitch in the same row or the same column, for example. The control circuits 41 in the same group are connected in series as shown in FIG. 4. A signal from the pad 343 arranged for each group is transmitted to the control circuit 41 in the group.

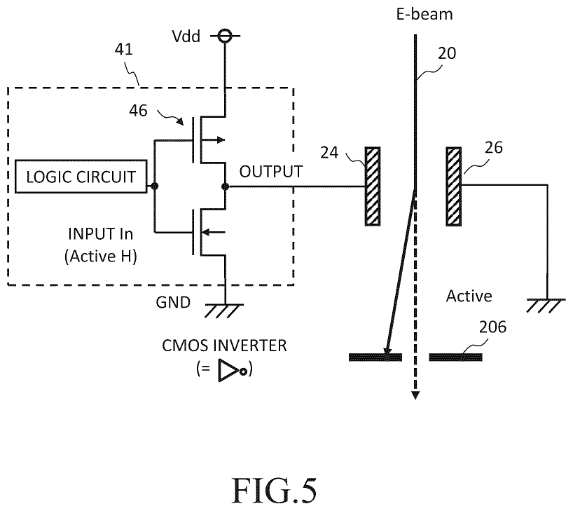

FIG. 5 is a circuit diagram showing an example of an individual blanking mechanism according to the first embodiment. As shown in FIG. 5, an amplifier 46 (an example of a switching circuit) is arranged in the control circuit 41. In the case of FIG. 5, as an example of the amplifier 46, a CMOS (complementary MOS) inverter circuit serving as a switching circuit is arranged. As an input (IN) to the CMOS inverter circuit, either an L (low) electric potential (e.g., ground potential) lower than a threshold voltage, or an H (high) electric potential (e.g., 1.5 V) higher than or equal to the threshold voltage is applied as a control signal. According to the first embodiment, in a state where an L electric potential is applied to the input (IN) of the CMOS inverter circuit, the output (OUT) of the CMOS inverter circuit to be applied to the control circuit 41 becomes a positive potential (Vdd), and then, a corresponding beam 20 is deflected by an electric field due to a potential difference from the ground potential of the counter electrode 26 so as to be blocked by the limiting aperture substrate 206, thereby becoming in a beam OFF condition. In contrast, in a state (active state) where an H electric potential is applied to the input (IN) of the CMOS inverter circuit, the output (OUT) of the CMOS inverter circuit becomes a ground potential, and therefore, since there is no potential difference from the ground potential of the counter electrode 26, a corresponding beam 20 is not deflected, thereby becoming in a beam ON condition by letting the beam concerned pass through the limiting aperture substrate 206. Blanking control is performed by such deflection.

Then, based on an irradiation time control signal transmitted for each beam, each individual blanking mechanism 47 controls, for each beam, the irradiation time of the shot concerned individually by using a counter circuit.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers (first deflector: individual blanking mechanism 47) of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. Then, the electron beam which was deflected by the blanker of the blanking aperture array mechanism 204 deviates (shifts) from the hole in the center of the limiting aperture substrate 206 and is blocked by the limiting aperture substrate 206. In contrast, electron beams which were not deflected by the blanker of the blanking aperture array mechanism 204 pass through the hole in the center of the limiting aperture substrate 206 as shown in FIG. 1. Thus, the limiting aperture substrate 206 blocks each beam which was deflected to be in the OFF state by the individual blanking mechanism 47. Then, one shot of each beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by deflecting the multiple beams 20 by the main deflector 208 such that the beam irradiation position follows the movement of the XY stage 105. Ideally, the multiple beams 20 irradiating at a time are aligned at the pitch obtained by multiplying the arrangement pitch of a plurality of holes 22 in the shaping aperture array substrate 203 by the desired reduction ratio described above.

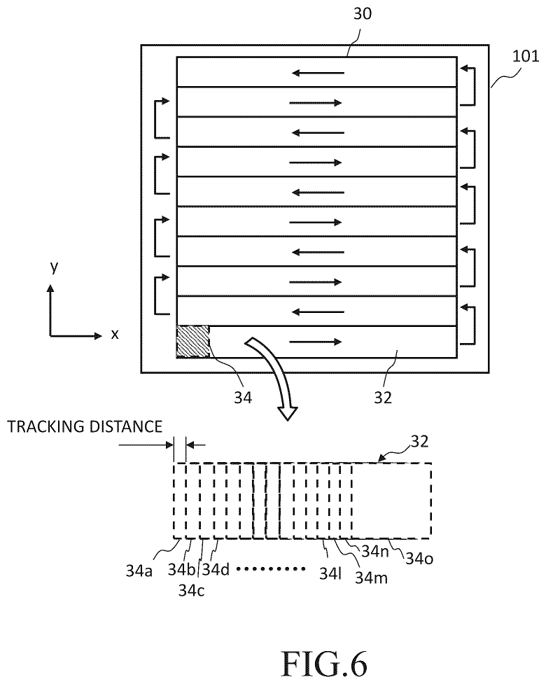

FIG. 6 is a conceptual diagram illustrating an example of a writing operation according to the first embodiment. As shown in FIG. 6, a writing region 30 of the target object 101 is virtually divided, for example, in the y direction by a predetermined width into a plurality of stripe regions 32 in a strip form. First, the XY stage 105 is moved to make an adjustment such that an irradiation region 34 which can be irradiated with one shot of the multiple beams 20 is located at the left end of the first stripe region 32 or at a position further left than the left end, and then writing is started. When writing the first stripe region 32, the writing proceeds relatively in the x direction by moving the XY stage 105 in the −x direction, for example. The XY stage 105 is moved, for example, continuously at a constant speed. After writing the first stripe region 32, the stage position is moved in the −y direction, and then, writing proceeds in the −x direction by moving the XY stage 105 in the x direction, for example. By repeating such operations, each stripe region 32 is written in order. The writing time can be reduced by performing writing while alternately changing the direction. However, the writing operation is not limited to the writing with alternately changing the direction, and it is also preferable to perform writing in the same direction when writing each stripe region 32. In the case of moving the XY stage 105 at a constant speed, the continuous movement speed may be different for each stripe. A plurality of shot patterns maximally up to as many as the number of a plurality of holes 22 in the shaping aperture array substrate 203 are formed at a time by one shot of multiple beams having been formed by passing through the holes 22 in the shaping aperture array substrate 203.

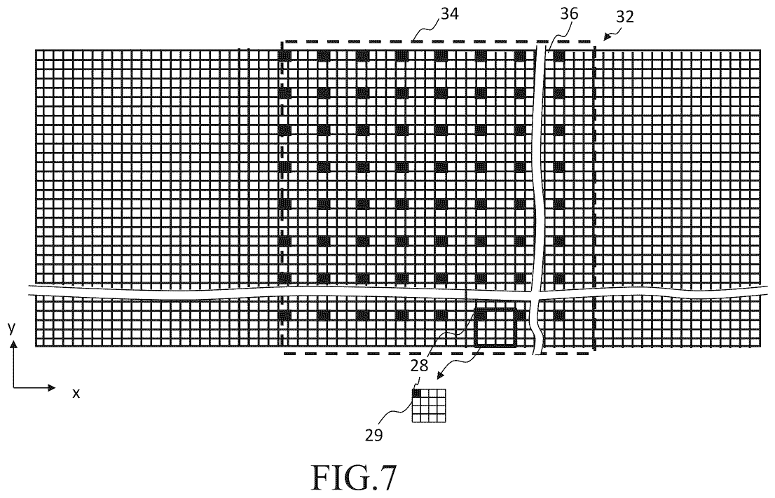

FIG. 7 is an illustration showing an example of an irradiation region of multiple beams and a pixel to be written (writing target pixel) according to the first embodiment. In FIG. 7, the stripe region 32 is divided into a plurality of mesh regions by the beam size of each of the multiple beams 20, for example. Each mesh region serves as a writing target pixel 36 (unit irradiation region, irradiation position, or writing position). The size of the writing target pixel 36 is not limited to the beam size, and may be any size regardless of the beam size. For example, it may be 1/a (“a” being an integer of 1 or more) of the beam size. FIG. 7 shows the case where the writing region 30 of the target object 101 is divided, for example, in the y direction, into a plurality of stripe regions 32 by the width size being substantially the same as the size of the irradiation region 34 (beam array region) which can be irradiated by one irradiation of the multiple beams 20. The x-direction size of the rectangular including square irradiation region 34 can be defined by (the number of beams in the x direction)× (beam pitch in the x direction). The y-direction size of the rectangular irradiation region 34 can be defined by (the number of beams in the y direction)× (beam pitch in the y direction). FIG. 7 shows the case of multiple beams of 500×500 (rows×columns) being simplified to 8×8 (rows×columns), for example. In the irradiation region 34, there are shown a plurality of pixels 28 (beam writing positions) which can be irradiated with one shot of the multiple beams 20. The pitch between adjacent pixels 28 on the target object is the beam pitch of the multiple beams. A sub-irradiation region 29 (pitch cell) is configured by a rectangular including square region surrounded by the size of a beam pitch in the x and y directions. Each sub-irradiation regions 29 includes one pixel 28. In the example of FIG. 7, the pixel at the upper left corner of each sub-irradiation region 29 indicates the pixel 28 serving as a beam writing position. Each sub-irradiation region 29 is composed of 10×10 pixels, for example. FIG. 7 shows the case where each sub-irradiation region 29 of 10×10 pixels is simplified to 4×4 pixels, for example.

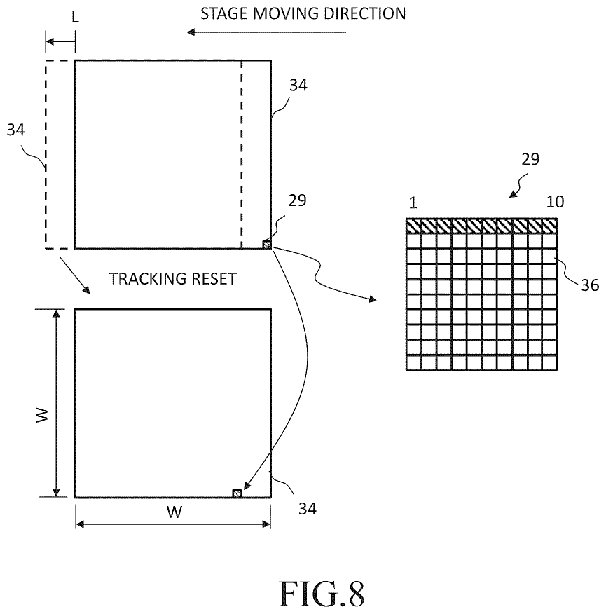

FIG. 8 is an illustration explaining an example of a multi-beam writing operation according to the first embodiment. FIG. 8 shows the case where the inside of each sub-irradiation region 29 on the target object 101 is written with ten different beams. The example of FIG. 8 shows a writing operation where the XY stage 105 continuously moves at the speed at which the XY stage 105 moves a distance L being twenty-five beam pitches while a 1/10 region, namely the region of 1/(the number of beams used for irradiation), in each sub-irradiation region 29 is written. In the writing operation shown in FIG. 8, for example, while the XY stage 105 moves the distance L of twenty-five beam pitches, ten different pixels in the same sub-irradiation region 29 are written (exposed) by applying ten shots of the multiple beams 20 at a shot cycle time t_{trk-cycle} with shifting the irradiation position (pixel 36) in order by the sub deflector 209. In order that the relative position between the irradiation region 34 and the target object 101 may not be shifted by the movement of the XY stage 105 while the ten pixels are written (exposed), the irradiation region 34 is made to follow the movement of the XY stage 105 by collective deflection of all of the multiple beams 20 by the main deflector 208. In other words, a tracking control is performed. Therefore, the distance L collectively deflected by the main deflector 208 during one tracking control serves as a tracking distance.

After one tracking cycle is completed, tracking is reset to return to the previous (last) tracking starting position. Since writing of the pixels in the first pixel row from the top of each sub-irradiation region 29 has been completed, in the next tracking cycle after resetting the tracking, first, the sub deflector 209 provides deflection such that the beam writing position is adjusted (shifted) to write the second pixel row from the top still not having been written in each sub-irradiation region 29, for example. Thus, whenever the tracking is reset, the pixel row to be written next is changed. While performing ten tracking controls, each pixel 36 in each sub-irradiation region 29 is written once. By repeating this operation during writing the stripe region 32, as shown in FIG. 6, the position of the irradiation region 34 is sequentially moved (shifted), such as 34a to 34o, to write the stripe region 32 concerned.

In the example of FIG. 8, the sub-irradiation region 29 on the target object surface, located in the lower right corner of the irradiation region 34 of the width W, moves leftward by the distance L from the lower right corner of the irradiation region 34 by the second tracking control. Therefore, the sub-irradiation region 29 located in the lower right corner of the irradiation region 34 in the first tracking control is written by another beam at the position away by the distance L in the left direction from the lower right corner of the irradiation region 34 in the second tracking control. Here, for example, writing is performed by the beam away by the twenty-five beams in the −x direction from the beam in the lower right corner.

For example, in the writing processing where the multiplicity is set to 2 per one pass of the stage, each pixel 36 in each sub-irradiation region 29 may be written twice by twenty-time tracking controls.

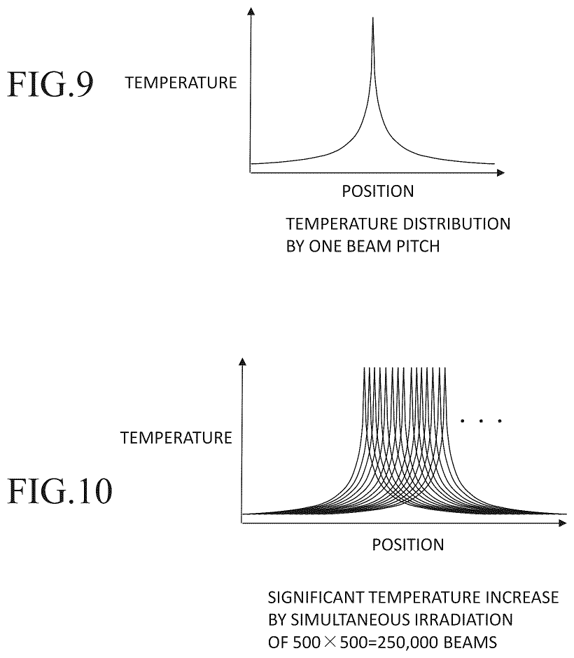

FIG. 9 is a graph showing an example of a relationship between a temperature distribution and a temperature resulting from applying one beam irradiation to a region of one beam pitch according to a comparative example of the first embodiment. In FIG. 9, the ordinate axis represents a temperature and the abscissa axis represents a temperature distribution. As shown in FIG. 9, the temperature distribution resulting from one beam irradiation has a wide footing region. Therefore, the influence affects a wide range. However, the influence on the footing region is small such as a temperature increase of at most 0.01° C. or less by one beam.

FIG. 10 is a graph showing an example of a relationship between a temperature distribution and a temperature resulting from applying a simultaneous multiple beam irradiation according to the first embodiment. In FIG. 10, the ordinate axis represents a temperature and the abscissa axis represents a temperature distribution. Although the temperature increase by one beam is at most 0.01° C. or less, if simultaneously applying an irradiation of, for example, 500×500=250,000 beams, the temperature increase by each beam overlaps with each other at the footing region as shown in FIG. 10. As a result, the simultaneous irradiation of 500×500=250,000 beams gives a significant temperature increase at the footing region.

Although a technique on estimation/correction of heating effect in a single beam writing is known, there is no previous example about correction of heating effect in multiple beam writing where simultaneous irradiation of, for example, 500×500=250,000 beams is performed many times at each time of_continuous movement of the stage (per one stage pass). In view of a calculation volume, it is not practical to calculate the heat generated by each of 250,000 beams similarly to the case of a single beam.

Since the current density J of multiple beams is extremely small compared with that of a VSB single beam, for example, the temperature increases slowly. During this increase period, the temperature distribution by one shot has diffused (spread) by several tens of micrometers. Therefore, even when calculation is performed by dividing shot data and dose data in a stripe into some combinations, sufficient accuracy can be obtained. As described above, since a raster scan method is used in multiple beam writing, the position is determined depending on time. Accordingly, once the dose data and the writing speed (stage speed or tracking cycle time) are determined, an increase temperature is also determined. Therefore, simpler correction can be performed compared with the VSB method which requires both the position and time.

Then, in the first embodiment, dose information on the stripe region 32 is assigned to pixel information of Nₓ×N_{y} pixels that includes a target mesh whose temperature is to be obtained. With respect to the target mesh, a temperature at each of a plurality of beam irradiation is calculated. Then, a statistic value (e.g., average value) of calculated temperatures is used, as an effective temperature, for correction. It is specifically described below.

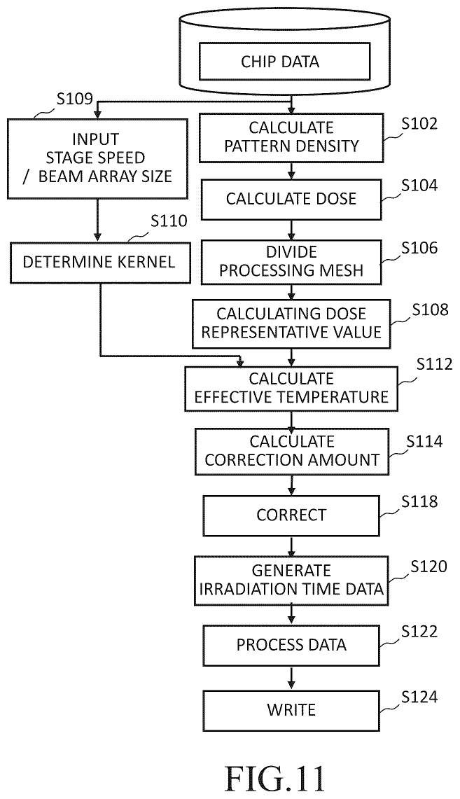

FIG. 11 is a flowchart showing an example of main steps of a writing method according to the first embodiment. In FIG. 11, the writing method of the first embodiment executes a series of steps: a pattern density calculation step (S102), a dose calculation step (S104), a processing mesh dividing step (S106), a dose representative value calculation step (S108), a stage speed and beam array size input step (S109), a kernel determination step (S110), an effective temperature calculation step (S112), a correction amount calculation step (S114), a correction step (S118), an irradiation time data generation step (S120), a data processing step (S122), and a writing step (S124).

First, writing data is read from the storage device 140 for each stripe region 32.

In the pattern density calculation step (S102), the pattern density calculation unit 50 calculates a pattern density p (pattern area density) for each pixel 36 in the target stripe region 32. The pattern density calculation unit 50 generates, for each stripe region 32, a pattern density map by using a calculated pattern density p of each pixel 36. The pattern density of each pixel 36 is defined as each element of the pattern density map. The generated pattern density map is stored in the storage device 144.

In the dose calculation step (S104), the dose calculation unit 52 calculates, for each pixel 36, a dose (irradiation amount) to be applied to the pixel 36 concerned. For example, the dose can be calculated by multiplying a pre-set base dose D_{base} by a proximity effect correction irradiation coefficient Dₚ and a pattern density p. Thus, it is preferable to obtain the dose to be in proportion to a pattern area density having been calculated for each pixel 36. With respect to the proximity effect correction irradiation coefficient Dₚ, the writing region (here, e.g., the stripe region 32) is virtually divided into a plurality of proximity mesh regions (mesh regions for proximity effect correction calculation) by a predetermined size. The size of the proximity mesh region is preferably about 1/10 of the influence range of the proximity effect, such as about 1 μm. Then, writing data is read from the storage device 140, and, for each proximity mesh region, a pattern area density ρ′ of a pattern arranged in the proximity mesh region concerned is calculated.

Next, the dose calculation unit 52 calculates, for each proximity mesh region, a proximity effect correction irradiation coefficient Dₚ for correcting a proximity effect. Here, the size of the mesh region to calculate the proximity effect correction irradiation coefficient Dₚ does not need to be the same as that of the mesh region to calculate a pattern density ρ′. Further, the correction model of the proximity effect correction irradiation coefficient Dₚ and its calculation method may be the same as those used in the conventional single beam writing method.

Then, the dose calculation unit 52 generates, for each stripe region 32, a dose map (1) by using a calculated dose of each pixel 36. The dose of each pixel 36 is defined as each element of the dose map (1). Although, in the above, the case of calculating a dose as an absolute value multiplied by the base dose D_{base} is described, it is not limited thereto. Assuming that the base dose D_{base} is 1, the dose may be calculated as a relative value to the base dose D_{base}. In other words, the dose may be calculated as a coefficient value obtained by multiplying the proximity effect correction irradiation coefficient Dₚ by the pattern density ρ. The generated dose map (1) is stored in the storage device 144.

In the processing mesh dividing step (S106), the dividing unit 53 (dividing processing circuit) divides the writing region of the target object 101, in the writing direction and a linearly independent direction to the writing direction, into a plurality of processing meshes 39 (mesh regions). In other words, the dividing unit 53 (dividing processing circuit) divides the inside of each of a plurality of stripe regions, which are obtained by dividing the writing region of the target object, in the y direction (the first direction), by the y direction size of the beam array region of the multiple charged particle beams on the target object surface, into a plurality of mesh regions by dividing in the y direction and the x direction (the second direction) parallel to the stage movement direction (−x direction) along each stripe region. Specifically, for example, the dividing unit 53 (dividing processing circuit) divides the inside of each stripe region 32 into a plurality of processing meshes (mesh regions), in the y direction (the first direction), by the size of 1/N_{y} of the size W of the beam array region, and in the x direction (the second direction), being perpendicular to the y direction, by the size of 1/Nₓ of the size W of the beam array region, where each of Nₓ and N_{y} is an integer of 2 or more.

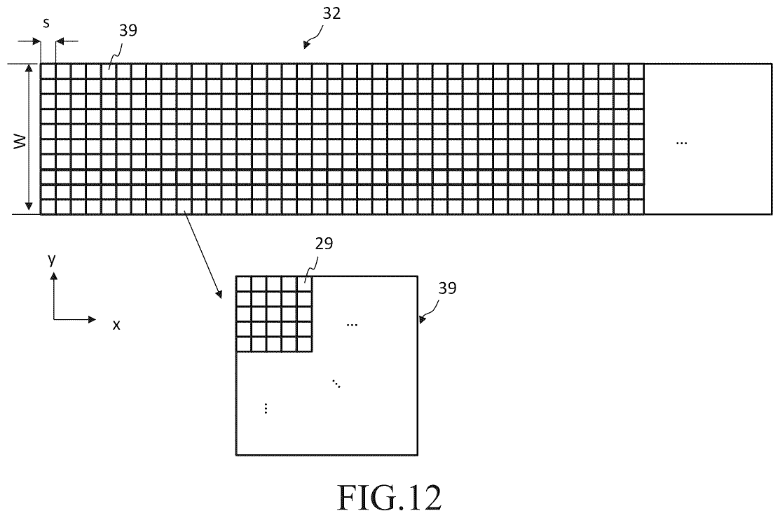

FIG. 12 is an illustration showing an example of a processing mesh according to the first embodiment. As described above, the writing region 30 of the target object 101 is divided in the y direction into a plurality of stripe regions 32, for example, by the size W of the irradiation region 34 (beam array region) of the multiple beams 20 on the target object 101 surface. Then, each stripe region 32 is divided into a plurality of processing meshes (mesh regions) 39, in the y direction by the size of 1/N_{y} of the size W of the irradiation region 34 (beam array region), where N_{y} is an integer of 2 or more, and, in the x direction by the size of 1/Nₓ of the size W of the irradiation region 34 (beam array region), where Nₓ is an integer of 2 or more. The x-direction size sₓ and the y-direction size s_{y} of each processing mesh 39 are larger than the sub-irradiation region 29 being a beam pitch size. In the example of FIG. 12, the x-direction size sₓ and the y-direction size s_{y} of each processing mesh 39 are of the same size s.

According to the first embodiment, preferably, the size s of the processing mesh 39 is set to the tracking distance L. The tracking distance L is k times (k being a natural number) the pitch size between beams on the surface of the target object 101. In the example described above, the tracking distance L is set to twenty-five times the beam pitch size, for example. Therefore, it is preferable to set the size s of the processing mesh 39 to be the size of twenty-five beam pitches. Thus, the size s of the processing mesh 39 is larger than that of the beam pitch on the target object 101 surface. Needless to say, the processing mesh 39 becomes a sufficiently large region compared with the pixel 36 used as a unit region to be irradiated with each beam.

In the dose representative value calculation step (S108), the dose representative value calculation unit 54 (dose statistic value calculation circuit) calculates a representative value of doses of beams to be applied to the inside of the processing mesh 39 concerned, as a dose representative value D, in each of a plurality of processing meshes 39 (mesh regions) obtained by dividing, in the writing direction and a linearly independent direction to the writing direction, the writing region of the target object 101 irradiated with the multiple beams 20. In other words, the dose representative value calculation unit 54 (dose statistic value calculation circuit) calculates, for each divided processing mesh 39, a representative value of a plurality of doses of a plurality of beams irradiating the inside of the processing mesh 39 concerned, as a dose representative value D. The processing mesh 39 includes a plurality of sub-irradiation regions 29. As described above, each sub-irradiation region 29 is irradiated with a plurality of different beams. In the example described above, each sub-irradiation region 29 is irradiated with, for example, ten different beams 25 away from each other in the x direction by twenty-five beam pitches, and a plurality of pixels 36 are included in the processing mesh 39. Here, a representative value (dose representative value Dᵢⱼ) of doses defined for all the pixels 36 in the processing mesh 39 is calculated. As the representative value, for example, an average, a maximum, a minimum, or a median can be used. Here, for example, an average dose being an average value is calculated as the dose representative value Dᵢⱼ. The dose representative value calculation unit 54 generates a dose representative value map by using a calculated dose representative value Dᵢⱼ of each processing mesh 39. The dose of each processing mesh 39 is defined as each element of the dose representative value map. “i” indicates an index in the x direction of the processing mesh 39, and “j” indicates an index in the y direction of the processing mesh 39. The generated dose representative value map is stored in the storage device 144.

According to the first embodiment, an effective temperature of each processing mesh 39 is calculated as will later be explained in the effective temperature calculation step (S112). First, the description is provided with respect to an effective temperature.

Calculation processing is performed for an increased temperature given to a target mesh region, being one of a plurality of the processing meshes 39, by heat due to a beam irradiation to each processing mesh 39 in a processing region corresponding to a beam array region. This calculation processing is executed by convolution processing using a dose representative value of each processing mesh 39 and a heat diffusion function indicating a heat diffusion (spread) in the processing mesh 39.

Repetition processing of repeating the above calculation processing is performed while shifting, in the x direction, the position of the processing region corresponding to a beam array region in the stripe region. This repetition processing is performed a plurality of times until the processing mesh 39 moves in the x direction from one end to the other end of the processing region in order to obtain a plurality of increased temperatures. A representative value of these obtained increased temperatures is individually calculated as an effective temperature of the mesh region concerned. Specifically, an effective temperature is calculated, for each processing mesh 39, using a dose statistic value Dᵢⱼ of each processing mesh 39 and a heat diffusion function PSF indicating a heat diffusion in each mesh. The heat diffusion function PSF can be defined by the following equation (1) as a general heat diffusion equation.

$$\frac{\partial T}{\partial t} = λ ( \frac{{\partial }^{2} T}{\partial {x}^{2}} + \frac{{\partial }^{2} T}{\partial {y}^{2}} + \frac{{\partial }^{2} T}{\partial {z}^{2}} ) \qquad ( 1 )$$

The function representing a surface temperature of a quartz glass substrate obtained from the equation (1) can be used as the heat diffusion function PSF. Here, A indicates thermal diffusivity of a substance diffused due to a temperature. The solution of the upper equation will be exemplified later with reference to the equation (3-1). Processing of a convolution operation of calculating, using a dose representative value Dᵢⱼ and a heat diffusion function PSF, an increased temperature of a mesh region concerned given by a heat due to beam irradiation to each processing mesh 39 in a processing region being a rectangular region of the same size as a beam array region composed of, for example, Nₓ×N_{y} processing meshes 39 is performed while shifting the rectangular region in the x direction by the size s of the processing mesh 39 in a target stripe region 32 until the mesh region concerned is included in the rectangular region. This processing is performed N times until the mesh region concerned moves from one end to the other end in the x direction of the rectangular region. A statistic value of a result of the N-time convolution operations is calculated as an effective temperature T(k,l).

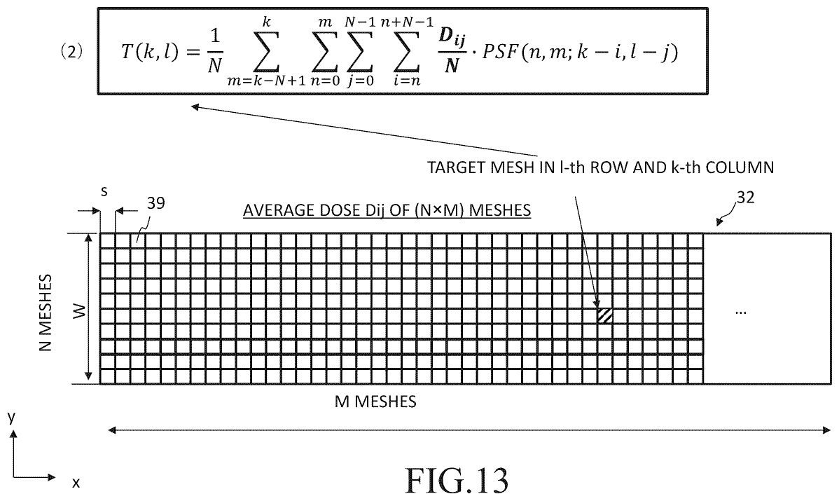

FIG. 13 is an illustration explaining a method of calculating an effective temperature according to the first embodiment. An effective temperature T(k,l) can be defined by the equation (2) shown in FIG. 13. In the stripe region 32, there are arranged M processing meshes 39 in the x direction and N processing meshes 39 in the y direction. The equation (2) shows, as a target mesh region, the processing mesh 39 in the 1-th row, where rows are arrayed in the y direction, and the k-th column, where columns are arrayed in the x direction, in a plurality of processing meshes 39 in the stripe region 32.

In the equation (2), i indicates an index in the x direction in a dose statistic value map. It is defined as index i=0 in the x direction of the processing mesh 39 at the left end of the stripe region 32.

j indicates an index in the y direction in the dose statistic value map. It is defined as index j=0 in the y direction of the processing mesh 39 at the lowest part of the stripe region 32.

N indicates the number of meshes in the longitudinal direction (y direction) of an input dose map used for calculating an effective temperature.

M indicates the number of meshes in the lateral direction (x direction) of the input dose map used for calculating an effective temperature.

(k,l) indicates an index (reference number) of a processing mesh (target mesh region) for which an effective temperature T is calculated in (M×N) processing meshes.

Dᵢⱼ indicates a dose representative value of the processing mesh 39 assigned to the index (k,l) in a dose representative value map. (μC/cm\hat{ }2)

m indicates a number of beam irradiation from the (1−N+1)th to the first beam irradiation performed until the beam array region (N×N, here, Nₓ=N_{y}=N) has passed through the target mesh (k,l). If the processing mesh size s is set to the tracking distance L, m is coincident with the (1−N+1)th to the first tracking reset number performed until the beam array region has passed through the target mesh (k,l). When m=l−N+1, a target mesh is located at the right end of the (N×N) beam array regions. When m=l, a target mesh is located at the left end.

n indicates a beam irradiation number from the 0th to the m-th beam irradiation number. If the processing mesh size s is set to the tracking distance L, n is coincident with the 0th to the m-th tracking reset number.

Since the first tracking control (tracking cycle) has not performed a tracking reset yet, its tracking reset number is zero. Since the second tracking control has performed a tracking reset once, its tracking reset number is 1.

PSF (n,m,k−i,l−j) indicates a heat diffusion function.

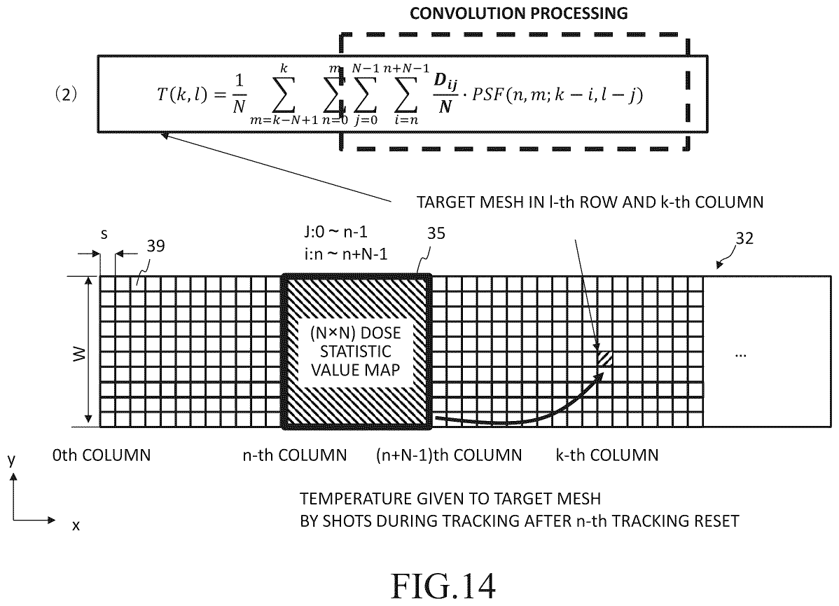

FIG. 14 is an illustration explaining a portion of an equation for calculating an effective temperature according to the first embodiment. In FIG. 14, the portion surrounded by dotted lines shows a calculation portion of convolution processing in the equation (2). In the calculation portion of the convolution processing in the equation (2), a convolution operation is performed for calculating an increased temperature of a target mesh region of the index (k,l) given by a heat due to beam irradiation to each mesh region in the rectangular region 35 of the same size as the beam array region composed of N×N processing meshes 39. The rectangular region 35 is used whose left end is at the n-th column of the processing mesh 39 and right end is at the (n+N−1)th column of the processing mesh 39. Therefore, the N×N processing meshes 39 corresponding to columns in the x direction from the n-th column to the (n+N−1)th column and to the rows in the y direction from the 0th row to the (N−1)th row are arranged in the rectangular region 35.

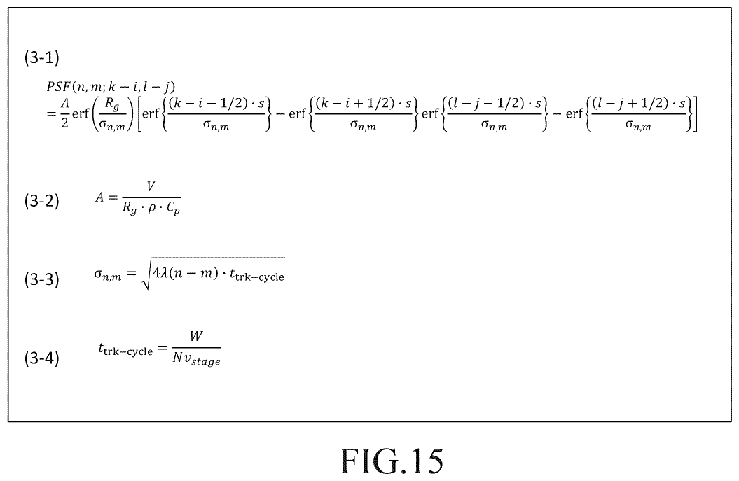

FIG. 15 is an illustration explaining an example of an equation of a heat diffusion function according to the first embodiment. The heat diffusion function PSF (n,m,k−i,l−j) is defined by the equation (3-1) shown in FIG. 15. Under initial conditions of the case where a uniform heat is given to the volume acquired by multiplying the mesh size by R_{g} due to beam irradiation to the substrate surface, the equation (3-1) can be obtained by solving a heat conduction equation under boundary conditions of being infinite in the x and y directions and semi-infinite in the z direction along the substrate depth direction. The signs, which are the same as those in the equation (2), in the heat diffusion function PSF(n,m,k−i,l−j) indicate the same meaning as those in the equation (2). The heat diffusion function PSF(n,m,k−i,l−j) shown in FIG. 15 defines the case where the XY stage 105 moves, at a constant speed, in the reverse direction (−x direction) to the x direction serving as the writing direction, for example. As shown in FIG. 15, the heat diffusion function PSF(n,m,k−i,l−j) is defined using a tracking cycle time obtained from the speed v of the XY stage 105.

In the equation (3-1), R_{g} indicates the range of an electron beam of 50 kV in quartz. For example, the range R_{g}=(0.046/ρ)E^{1.75} is used.

ρ indicates the density (e.g., 2.2 g/cm\hat{ }3) of the substrate (quartz).

σ_{n,m} indicates a function determined by the number of times (m−n) of tracking resets performed during the n-th and the m-th tracking resets. The function σ_{n,m} is defined by the equation (3-3).

The function A is defined by the equation (3-2).

In the equation (3-2), V indicates an acceleration voltage of an electron beam.

Cₚ indicates a specific heat (e.g., 0.77 J/g/K) of the substrate (quartz).

In the equation (3-3), λ indicates a heat diffusivity (e.g., 0.0081 cm\hat{ }2−/sec) of the substrate (quartz).

(m−n) indicates the number of times of tracking resets performed during the n-th and the m-th tracking resets.

t_{trk-cycle} indicates a tracking cycle time. The tracking cycle time t_{trk-cycle} is defined by the equation (3-4).

v_{stage} indicates a stage speed.

In a multi-beam writing apparatus, generally, it is optimized so that shots (ten shots in a previous example) may be completed during a time between tracking operations, while moving at the stage speed v_{stage}=(fixed) in a stage pass. Since the movement of the tracking distance L(=W/N) is followed at the stage speed, the tracking cycle time t_{trk-cycle} can be defined by the equation (3-4).

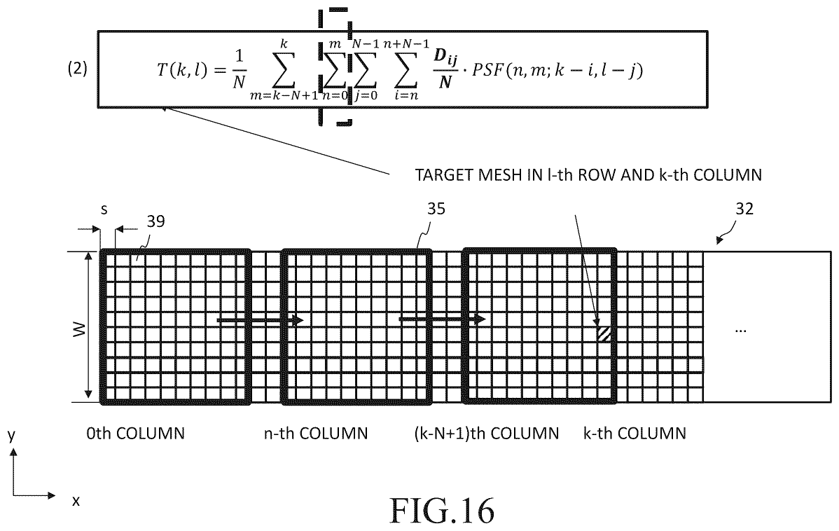

FIG. 16 is an illustration showing another portion of the equation for calculating an effective temperature according to the first embodiment. The convolution processing described with reference to FIG. 14 is performed while shifting the rectangular region 35 in the x direction from the left end (n=0) of the stripe region 32 by the size s of the processing mesh 39 until the target mesh region of index (k,l) is included in the rectangular region 35 (that is, until it becomes n=m). This processing is shown in the calculation portion surrounded by dotted lines in the equation (2) of FIG. 16. FIG. 16 shows the case where the rectangular region 35 is moved until the target mesh region of index (k,l) is located at the right end of the rectangular region 35. In this state, the left end of the rectangular region 35 is located in the (k−N+1)th column and the right end is located in the k-th column.

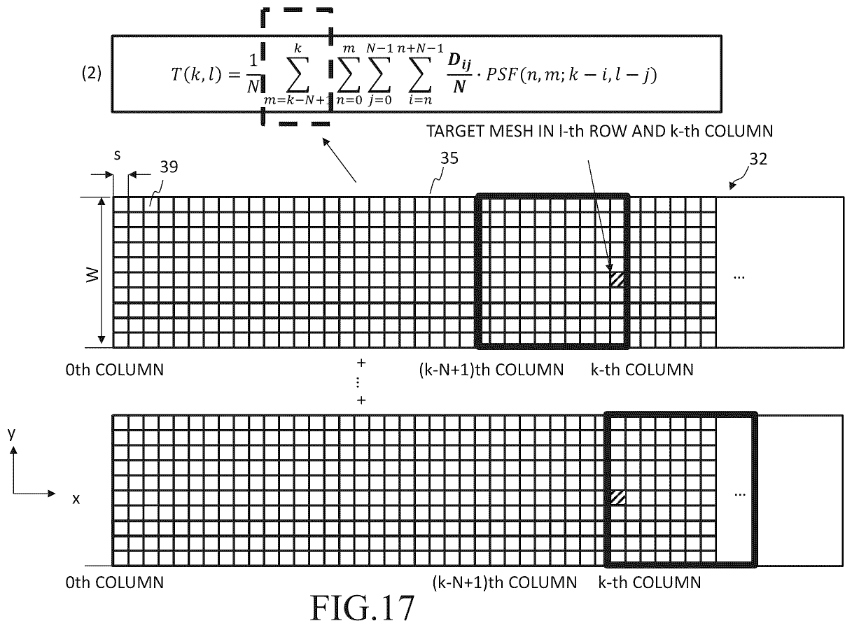

FIG. 17 is an illustration showing another portion of the equation for calculating an effective temperature according to the first embodiment.

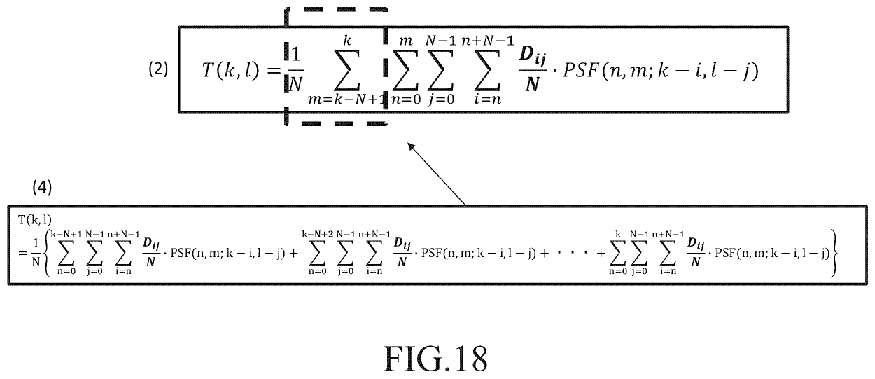

FIG. 18 is also an illustration showing another portion of the equation for calculating an effective temperature according to the first embodiment. FIG. 18 specifically shows the processing performed in the calculation portion of FIG. 17.

As shown in FIG. 17, the processing of FIG. 16 is performed N times until the target mesh region moves in the x direction from being located at one end (right end) of the rectangular region 35 to being located at the other end (left end). In other words, as shown in the equation (4) of FIG. 18, processing described below is performed N times in order to obtain the total of them: the processing from n=0 to n=m=k−N+1 shown in FIG. 16, the processing from n=0 to n=m=k−N+2 shown in FIG. 16, the processing from n=0 to n=m=k−N+3 shown in FIG. 16, . . . and the processing from n=0 to n=m=k shown in FIG. 16. Since N processing meshes 39 are arranged in the x direction in the rectangular region 35, processing is performed N times until a target mesh region is located at the left end starting from the right end of the rectangular region 35. This processing is shown in the calculation portion surrounded by dotted lines in the equation (2) of FIG. 17. Then, a statistic value of the result of the N-time convolution processing is obtained as an effective temperature T(k,l). This processing is shown in the calculation portion surrounded by dotted lines in the equation (2) of FIG. 18. The equation (2) shows the case where an average value acquired by dividing the total of the N-time convolution processing by N is calculated as an effective temperature T(k,l). The division number of the rectangular region and the number of times of calculation processing do not necessarily need to be coincident. That is, it is acceptable to divide into N, and to have a number smaller than N as the number of times of calculation (down sampling). Further, it is also acceptable to divide into N, and distribute them to meshes whose number is larger than N_(up sampling).

The effective temperature T(k,l) is not limited to an average value, and may be a maximum, a minimum, or a median of a result of N-time convolution processing. Desirably, a median is used. More desirably, an average is used.

While changing the position of a target mesh region, an effective temperature T(i,j) is calculated for each position (i,j) of the processing mesh 39.

As described above, not by calculating an increased temperature per shot per beam, but by calculating using a dose representative value Dᵢⱼ of the processing mesh 39, an effective temperature T(i,j) per processing mesh 39 is obtained. The effective temperature T(i,j) can be calculated for each processing mesh 39 which is sufficiently larger than the pixel 36 used as a unit region to be irradiated with a beam per shot. Therefore, the calculation amount can be largely reduced.

Although it is preferable to calculate an effective temperature T each time using the method described above, a further improvement is given, in the first embodiment, to the above method of calculating the effective temperature T.

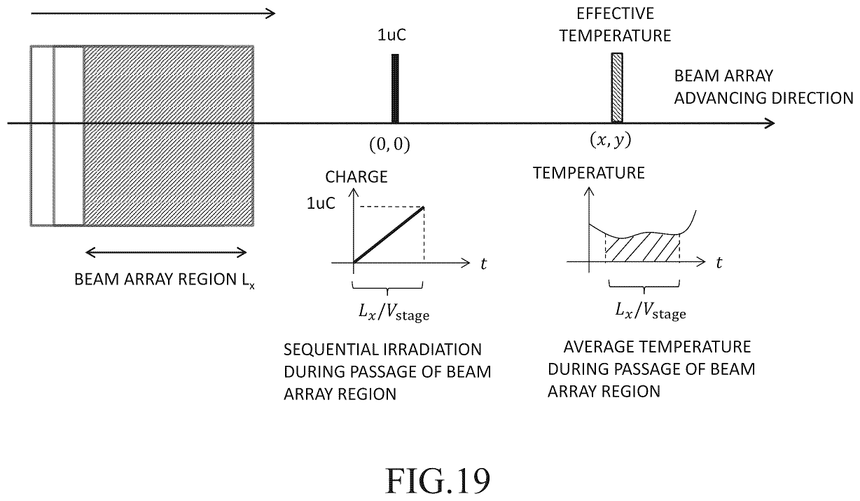

FIG. 19 is an illustration showing an example of a virtual model of an effective temperature according to the first embodiment. In FIG. 19, when point irradiation with an electric charge of 1 μC is performed to a position of coordinates (0,0) in a multi-beam writing system, a kernel is obtained by calculating an effective temperature (average temperature of a period while BAA region passing through a region (x,y)) measured at any desired position (x,y). In the graph illustrated below the position coordinates (0,0) of FIG. 19, the ordinate axis represents an electric charge amount, and the abscissa axis represents a time t. In the graph illustrated below the any desired position coordinates (x,y), the ordinate axis represents a temperature, and the abscissa axis represents a time t.

As shown in the graph illustrated below the position coordinates (0,0) of FIG. 19, it is assumed that the beam array region of size Lₓ in the x direction moves continuously and linearity at the stage speed V_{stage}, and an electric charge is continuously and linearity irradiated. Further, it is assumed that the irradiation is started at the right end of the beam array region, and completed at the left end. Under these two assumptions, an effective temperature at any desired position (x,y) is approximately calculated. The graph illustrated below the position coordinates (0,0) of FIG. 19 shows a state of irradiation applied sequentially during a period of the passage of the beam array region. As shown in the graph illustrated below the any desired position (x,y), the temperature increases during the time (t=Lₓ/V_{stage}) of point irradiation to the position coordinates (0,0) by the beam array region, and before and after that time. The effective temperature indicates an average temperature during the passage of the beam array region.

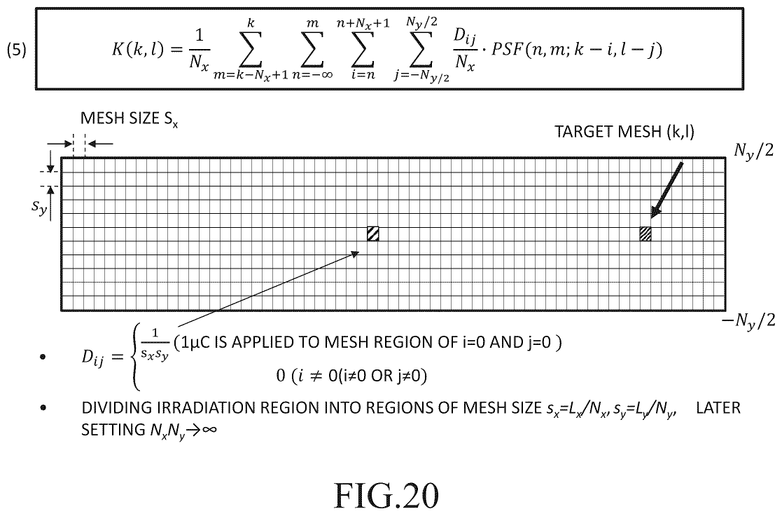

FIG. 20 is an illustration showing an example of a kernel derivation process according to the first embodiment. In the stripe region 32, M processing meshes 39 in the x direction and N_{y} processing meshes 39 in the y direction are arranged. If the intermediate position with respect to the y direction of the stripe region 32 is set to j=0, there are arranged from −N_{y}/2 to +N_{y}/2 processing meshes 39 in the y direction in the stripe region 32. If the intermediate position with respect to the x direction of the stripe region 32 is set to i=0, there are arranged from −∞ to M processing meshes 39 in the x direction in the stripe region 32, for example. In the equation (5), the processing mesh 39 which is located in the first row in the y direction and in the k-th column in the x direction serves as a target mesh region in a plurality of processing meshes 39 in the stripe region 32.

In FIG. 20, the x-direction size sₓ of the processing mesh 39 is a value obtained by dividing the x-direction beam array size Lₓ by the number of meshes, Nₓ, in the x direction in the beam array. The y-direction size s_{y} of the processing mesh 39 is a value obtained by dividing the y-direction beam array size L_{y} by the number of meshes, N_{y}, in the y direction in the beam array.

Here, it is assumed that point irradiation with an electric charge of 1 μC is performed to the mesh region whose position is i=0 and j=0. At this time, if the dose representative value Dᵢⱼ of the processing mesh at coordinates (0,0) is an average per unit area, it becomes Dᵢⱼ=1/(sₓs_{y}), where dose representative values of the processing mesh other than i=0 and j=0 are 0. The effective temperature T(k,l) in such a case is defined as the kernel T(k,l). The kernel T(k,l) can be defined by the equation (5) shown in FIG. 20. Since the method of setting an index has been changed as described above, the integral range of the right side of the equation (5) has been changed from that of the right side of the equation (2).

Here, it is assumed that Nₓ and N_{y} are (infinite). In other words, it is assumed that the size of the processing mesh is infinitesimal.

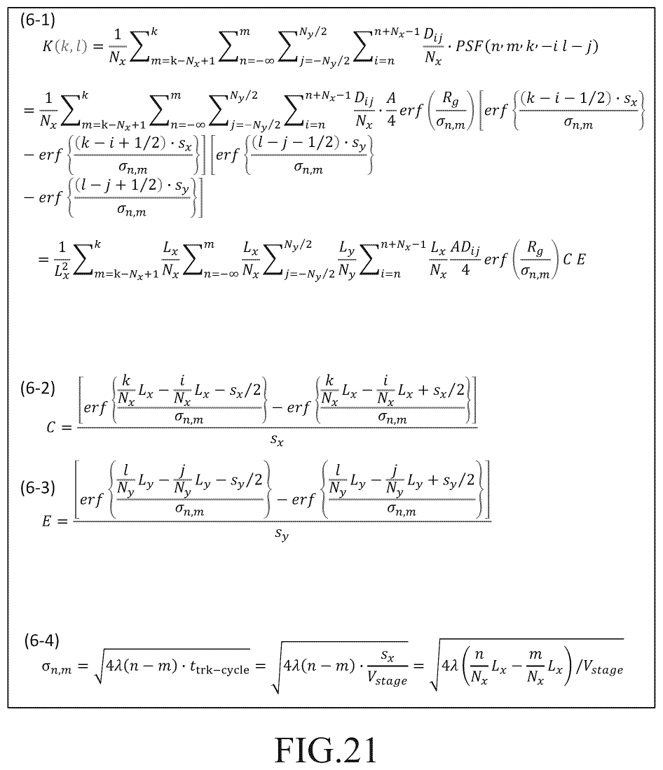

FIG. 21 is an illustration showing another example of a kernel derivation process according to the first embodiment. By setting the sizes sₓ and s_{y} of the processing mesh to be infinitesimal, the equation (5) can be converted as shown in the equation (6-1). The function C is shown in the equation (6-2). The function E is shown in the equation (6-3). Here, the heat diffusion function PSF is shown in the equations from (3-1) to (3-3). The tracking cycle time t_{trk-cycle} can be defined by a value obtained by dividing the processing mesh size sₓ in the x direction by the stage speed V_{stage}. The processing mesh size sₓ is a value obtained by dividing the x-direction size Lₓ of the beam array region by the number of meshes, Nₓ, in the x direction of the beam array region. In other words, a virtual tracking distance Lₓ/Nₓ is defined. Therefore, functions on and m in the equation (3-3) can be converted to the equation (6-4).

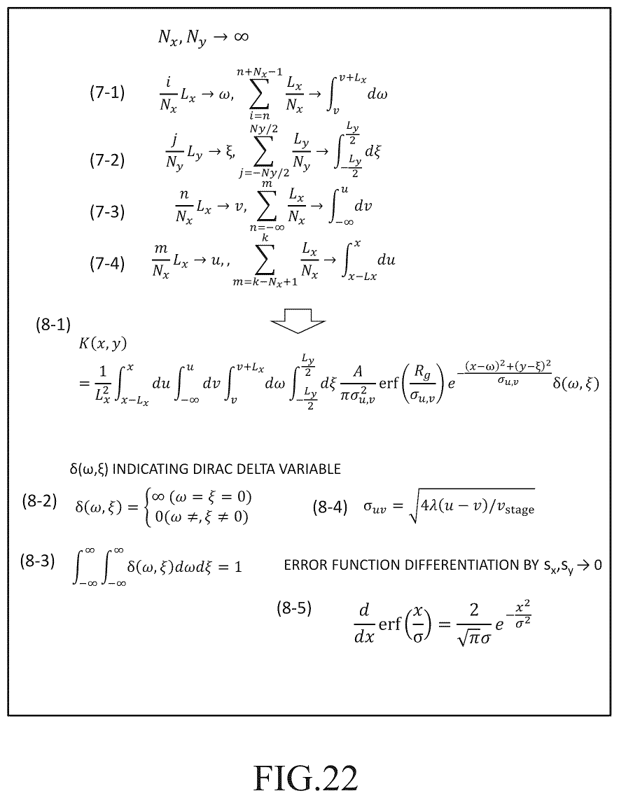

FIG. 22 is an illustration showing another example of a kernel derivation process according to the first embodiment. As described above, it is assumed that, in the processing region which overlaps with the beam array region, the numbers of meshes, Nₓ and N_{y}, are infinite. In other words, it is assumed that the size of the processing mesh 39 is infinitesimal. Then, in FIG. 22, an integral variable w is defined to be a value obtained by converting a quantity (first quantity) by setting an infinity for Nₓ, the quantity (first quantity) being calculated by dividing the reference number i, which indicates a mesh region in the beam moving direction (x direction) in a processing region of the same size as the beam array region, by the number of mesh regions, Nₓ, in the beam moving direction in the processing region overlapping with the beam array region, and multiplying the divided value by the size Lₓ of the beam array region in the beam moving direction.

Further, in FIG. 22, an integral variable is defined to be a value obtained by converting a quantity (second quantity) by setting an infinity for N_{y}, the quantity (second quantity) being calculated by dividing the reference number j, which indicates a mesh region in the y direction in a processing region of the same size as the beam array region, by the number of mesh regions, N_{y}, in the y direction in the processing region overlapping with the beam array region, and multiplying the divided value by the size L_{y} of the beam array region in the y direction.

Further, in FIG. 22, an integral variable u is defined to be a value obtained by converting a quantity (third quantity) by setting an infinity for Nₓ, the quantity (third quantity) being calculated by dividing the beam irradiation number m, which is m=k−Nₓ+1, k−Nₓ, and . . . k and indicates a number of beam irradiation sequentially performed Nₓ times until the processing region of the size of Nₓ×N_{y} mesh regions has passed through the target mesh (k,l), by the number of mesh regions, Nₓ, and multiplying the divided value by the size Lₓ of the beam array region in the writing direction (x direction).

Further, in FIG. 22, an integral variable v is defined to be a value obtained by converting a quantity (fourth quantity) by setting an infinity for Nₓ, the quantity (fourth quantity) being calculated by dividing the beam irradiation number n, which is a number of beam irradiation sequentially performed such as the m-th, (m−1)th, (m−2)th, . . . , by the number of mesh regions, Nₓ, and multiplying the divided value by the size Lₓ of the beam array region in the writing direction (x direction).

Thus, the convolution processing portion, which totals Lₓ/Nₓ from i=n to n+Nₓ−1 in the right side of the equation (6-1) defining the kernel K(k,l), can be defined as a term component indicating an integral operation for performing integration from v to v+Lₓ by using the integral variable w as shown in the equation (7-1).

Further, the convolution processing portion, which totals L_{y}/N_{y} from j=−L_{y}/2 to +L_{y}/2 in the right side of the equation (6-1) defining the kernel K(k,l), can be defined as a term component indicating an integral operation for performing integration from −L_{y}/2 to +L_{y}/2 by using the integral variable (as shown in the equation (7-2).

Further, the convolution processing portion, which totals Lₓ/Nₓ from n=−∞ to m in the right side of the equation (6-1) defining the kernel K(k,l), can be defined as a term component indicating an integral operation for performing integration from −∞ to u by using the integral variable v as shown in the equation (7-3).

Further, the convolution processing portion, which totals Lₓ/Nₓ from m=k−Nₓ+1 to k in the right side of the equation (6-1) defining the kernel K(k,l), can be defined as a term component indicating an integral operation for performing integration from x−Lₓ to x by using the integral variable u as shown in the equation (7-4).

Term component for performing integration using integral variables ω and ξ: integral operation performed, when a beam array region is located at a position v, for integrating an increased temperature given to the position (x,y) by a heat due to a beam applied to a certain position (ω,ξ) in the beam array region. Therefore, the integral range of ω and ξ is in the beam array region, ω becomes from v to v+Lₓ, and ξ becomes from −L_{y}/2 to +L_{y}/2.

Term component for performing integration using an integral variable v: integral operation performed, when a beam array region is located at each of the positions from infinity to the position u, for further integrating an increased temperature given to the position (x,y) and having been integrated by the above integration operation. Therefore, the integral range of v is from −∞ to u.

Term component for performing integration using an integral variable u: integral operation performed, from when one end of the beam array region is located at the position (x,y) to when the other end is located there, for further integrating an increased temperature having been integrated by the above integration operation. Therefore, the integral range of u is from x−Lₓ to x.

Accordingly, the kernel K(k,l) can be defined by an integral equation using integral variables ω, ξ, u, and v. Specifically, the kernel K(k,l) can be defined by the equation (8-1) which multiplies the term component indicating an integral operation using an integral variable ω, the term component indicating an integral operation using an integral variable ξ, the term component indicating an integral operation using an integral variable v, the term component indicating an integral operation using an integral variable u, a function A/(πσ_{u,v}²)erf(R_{g}/σ_{u,v})e\hat{ }(−((x−ω)²+(y−ξ)²)/σ_{u,v}), and a Dirac delta function δ(ω,ξ). The Dirac delta function δ(ω,ξ) satisfies the equations (8-2) and (8-3). Further, the function σ_{u,v} is defined by the equation (8-4). By setting the sizes sₓ and s_{y} of the processing mesh to be infinitesimal, a differential equation of an error function can be defined by the equation (8-5).

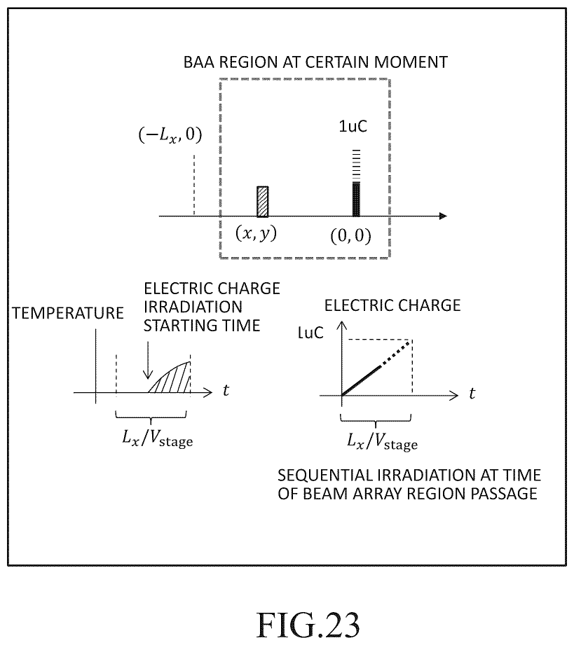

FIG. 23 is an illustration explaining a kernel according to the first embodiment. The kernel K(x,y) indicates, in the case of continuously applying an electric charge of 1 μC to (x,y)=(0,0) during a beam array region passage, an average temperature (effective temperature) during the passage of the beam array region at any desired position. The state of continuously applying an electric charge of 1 μC during the beam array region passage is shown at the lower right of FIG. 23. The ordinate axis represents an electric charge amount, and the abscissa axis represents a time. In such a case, as shown at the upper part of FIG. 23, an effective temperature not being zero appears in x>−Lₓ even at the backward of the electric charge irradiation point of coordinates (0,0). This is because the heat generated due to irradiation at the right end of the beam array region is given as a heating effect when the inside of the beam array region is irradiated as shown at the lower left of FIG. 23. That is, the kernel is dependent on the size Lₓ of the beam array region.

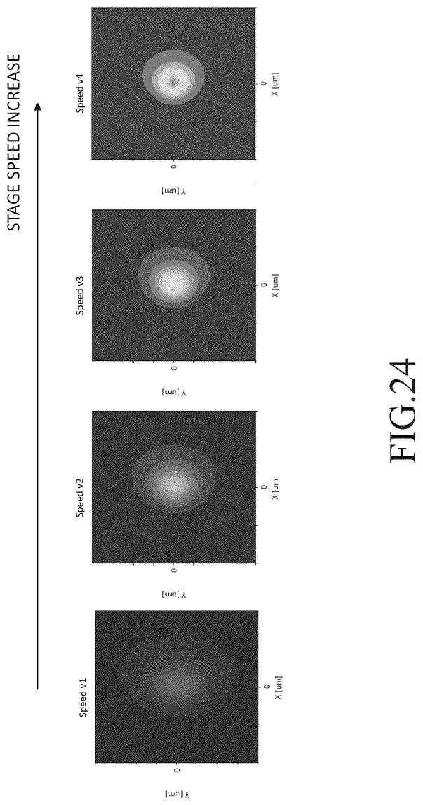

FIG. 24 is an illustration showing an example of a relationship between a stage speed and a kernel according to the first embodiment. FIG. 24 shows an example of four kernels whose stage speeds V_{stage} are different from each other such as V_{stage}=v1 to v4 under the condition that the x-direction size Lₓ of the beam array is fixed. As shown in FIG. 24, the temperature distribution of the kernel is an asymmetrical different height and shape for each stage speed. In the case of FIG. 24, it turns out that the temperature of the central part of the temperature distribution becomes high in accordance with an increase of the stage speed.

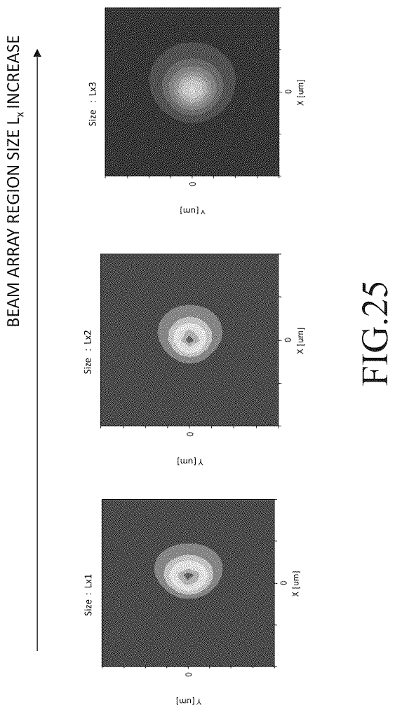

FIG. 25 is an illustration showing an example of a relationship between a moving direction size of a beam array and a kernel according to the first embodiment. FIG. 25 shows an example of three kernels whose x-direction size Lₓ of the beam array are different from each other such as Lₓ=Lₓ1 to Lₓ3 under the condition that the stage speed is fixed. As shown in FIG. 25, the temperature distribution of the kernel has different height and shape for each x-direction size Lₓ of the beam array. In the case of FIG. 25, it turns out that the temperature of the central part of the temperature distribution becomes high in accordance with a decrease of the x-direction size Lₓ of the beam array.

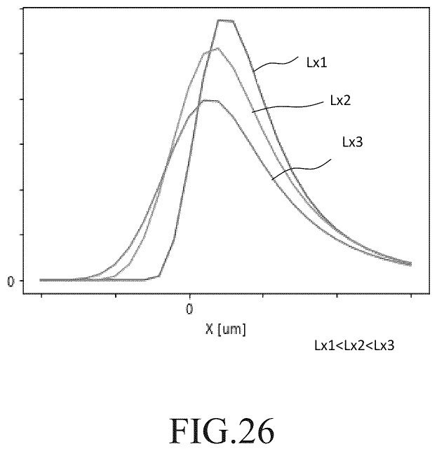

FIG. 26 is an illustration showing another example of a relationship between a moving direction size of a beam array and a kernel according to the first embodiment. FIG. 26 shows an example of a temperature distribution at each of the three x-direction sizes Lₓ of the beam arrays shown in FIG. 25. The ordinate axis represents a temperature and the abscissa axis represents a position in the x direction. As shown in the example of FIG. 26, depending on the size Lₓ of the beam array region, the shape of the temperature distribution of the kernel at the rise and fall differs from each other.

Therefore, according to the first embodiment, a plurality of kernels corresponding to the stage speed and the beam array size Lₓ are generated beforehand.

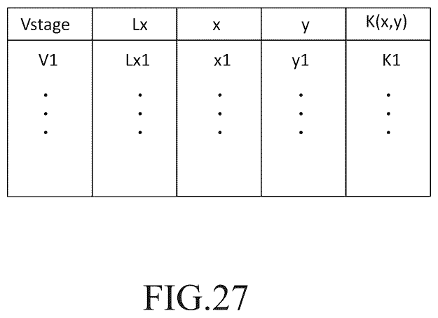

FIG. 27 is an illustration showing an example of a kernel defined as a table according to the first embodiment. In FIG. 27, the kernel K(x,y) is defined as a value of each position in a range larger than a beam array region. This is because there is an influence of residual heat after the beam array passes. When, for example, the size Lₓ of the beam array region is set within the range about 100 μm (maximum) to 10 μm (minimum), it is preferable that the kernel is calculated in the region of, for example, about ±300 μm in each of the x and y directions.

In the example of FIG. 27, the stage speed V_{stage}, the beam array x-direction (reverse to stage moving direction) size Lₓ, the position (x,y), and the kernel value K(x,y) at each position are relationally defined as a table. Assuming that point irradiation with an electric charge of 1 μC is performed to the center position of the kernel and the point irradiation is started at one end of the beam array region and completed at the other end while the beam array region is continuously moving at a constant speed, the value of the kernel K(x,y) at each position indicates a representative value of the temperature during a period while the beam array region passes through the position concerned under the above two assumptions. When referring to the stage speed actually used and the beam array region size, if there is no coincident value, it is sufficient to use a linearity complement value obtained from previous and subsequent values.

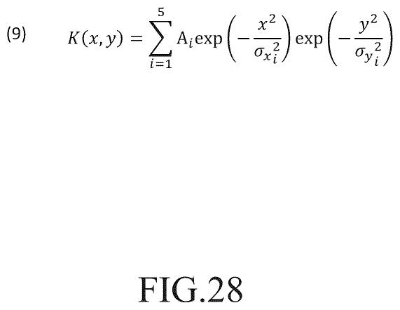

FIG. 28 is an equation representing an example of a kernel defined as a continuous function according to the first embodiment. In the example of FIG. 28, the equation (9) shows an example of a function calculated by approximating five kernels which are obtained by adding five Gaussian functions being anisotropic in the x and y directions and whose stage speeds are different from each other. A coefficient Ai is prepared for each stage speed. A speed between stage speeds defined in the table is indicated by coefficients Ai, σxi, and σyi having been linearity complemented. For example, an equation of the kernel defined as a continuous function can be prepared for each beam array region size Lₓ. Alternatively, it is also preferable to prepare a function obtained by approximating a plurality of kernels whose stage speeds and beam array region sizes Lₓ are different from each other.

As described above, according to the first embodiment, a plurality of kernels depending on the stage speed and the beam array region size Lₓ are prepared beforehand. The plurality of kernels are stored in the storage device 144.

In the stage speed and beam array size input step (S109), the obtaining unit 56 obtains the stage speed V_{stage} and the beam array size Lₓ for the current writing processing. Specifically, the obtaining unit 56 obtains the stage speed V_{stage} and the beam array size Lₓ having been set when writing conditions (not shown) were set. Setting of the writing conditions is performed through a manual input operation by the user. Alternatively, it is also preferable that a plurality of conditions with respect to a plurality of writing condition parameters including the stage speed V_{stage} and the beam array size Lₓ are set on the input screen (not shown) to be selected, and the user selects a writing condition parameter from the plurality of set conditions. The beam array size Lₓ changes, for example, when the number of beams are limited and used, in beam arrays irradiatable by the writing apparatus 100. Specifically, there is a case of using only the beam array of at the center part, in the beam arrays, where the influence of aberration is small. Thereby, since the number of beams is reduced, the writing position accuracy can be increased though the writing time becomes long.

In the kernel determination step (S110), the kernel determination unit 57 determines a corresponding kernel in a plurality of kernels, based on the acquired (input) stage speed V_{stage} and beam array size Lₓ.

In the effective temperature calculation step (S112), the effective temperature calculation unit 58 calculates, as an effective temperature T(k,l) of each of a plurality of processing meshes 39, a representative value of increased temperatures, which are individually given to the plurality of processing meshes 39 by heat due to beam irradiation, by performing convolution processing between a dose representative value and a kernel determined according to the speed of the stage 105 with the target object 101 thereon, and the size in the writing direction of the beam array region of the multiple beams 20 on the target object 101 surface. In other words, the effective temperature calculation unit 58 inputs the speed V_{stage} of the stage 105 and the size Lₓ of the beam array region in the x direction, and calculates, as an effective temperature T(k,l) of a target mesh region, a representative value of an increased temperature given to a target mesh region (k,l), which is one of a plurality of the processing meshes 39, by heat due to beam irradiation to a processing region of the same size as the beam array region overlapping with the beam array region on the target object 101 surface, by using a dose representative value and a kernel determined according to the speed V_{stage} of the stage 105 and the size Lₓ of the beam array region in the x direction. The calculated effective temperature is output to the memory 112 and/or the storage device 142, etc. to be stored therein. Specifically, it operates as follows:

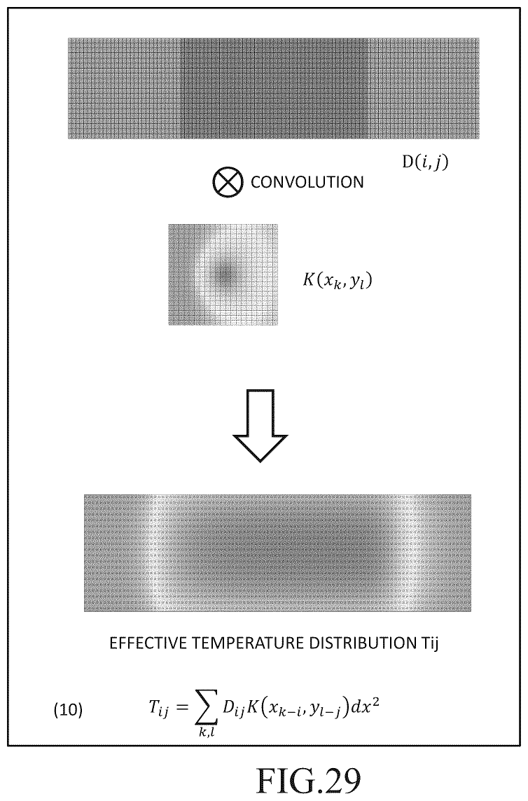

FIG. 29 is an illustration explaining a method of calculating an effective temperature according to the first embodiment. As shown in FIG. 29, the effective temperature calculation unit 58 performs convolution processing between the dose distribution of the dose representative value Dᵢⱼ and the kernel K(xₖ,yₗ). (xₖ,yₗ) indicates a position in the kernel. Thereby, the effective temperature T(k,l) of a target mesh can be calculated. The effective temperature T(k,l) of the target mesh can be defined by the equation (10) indicating the above convolution processing. In the convolution processing, while shifting a kernel center in the dose distribution, the sum of products of elements whose positions are coincident is calculated. The sum of products of elements, where the position of a kernel center is coordinates(k,l), serves as the effective temperature T(k,l).

In the example described above, the stage 105 moves at a constant speed, but, it is not limited thereto. The equation (10) can also be applied to the case where the stage 105 moves at a variable speed. In that case, a stage speed distribution is stored in the storage device 144. The effective temperature calculation unit 58 may acquire a stage speed at the position where a kernel center is located, and select and use a kernel corresponding to the stage speed at the position where the kernel center is located. Thereby, even when the stage 105 moves at a variable speed, the effective temperature can be calculated using the kernel described above.

In the correction amount calculation step (S114), the correction amount calculation unit 60 calculates, using the effective temperature of each of a plurality of mesh regions, doses of a plurality of beams to be applied to a target mesh region, being one of the plurality of mesh regions, in the multiple beams 20. For example, first, the correction amount calculation unit 60 calculates a modulation rate α(x) of a dose depending on the effective temperature T.

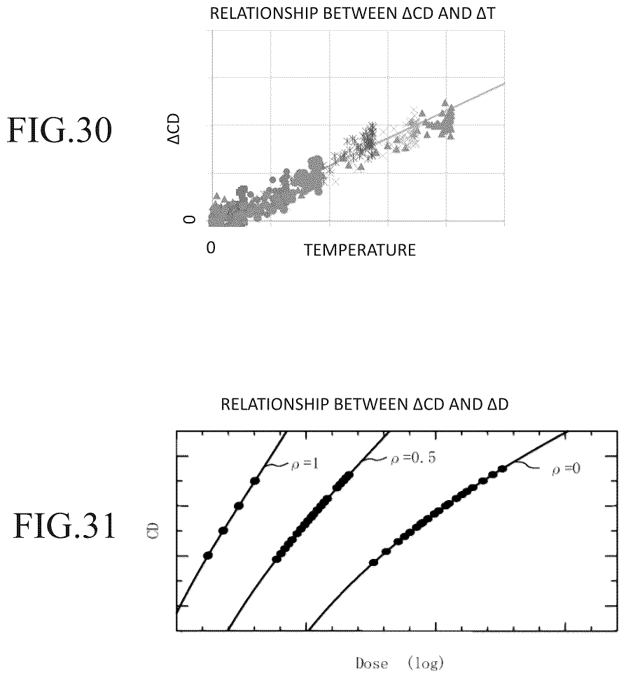

FIG. 30 is an illustration showing an example of a relationship between a line width (critical dimension CD) and a temperature according to the first embodiment. In FIG. 30, the ordinate axis represents a critical dimension, and the abscissa axis represents a temperature. It turns out, as shown in FIG. 30, that deviation (shift) of the critical dimension becomes large in accordance as the resist temperature increases. There is a linear relationship in a CD change ΔCD/ΔT[nm/K] due to a heating effect. Since this value varies depending on the kind of the resist and that of the substrate, an experiment is performed to acquire them. Then, an approximate equation for approximating a CD change amount ΔCD per unit temperature ΔT is obtained. Such correlation data (1) is input from the outside, and stored in the storage device 144.

FIG. 31 is an illustration showing an example of a relationship between a line width (critical dimension) CD and a dose according to the first embodiment. In FIG. 31, the ordinate axis represents a critical dimension, and the abscissa axis represents a dose. In the case of FIG. 31, logarithm is used for the abscissa axis. As shown in FIG. 31, the critical dimension depends on a pattern density, and it increases in accordance as the dose increases. An experiment is performed to acquire a relationship between a CD change and a dose, ΔCD/AD, for each kind of resist, each kind of substrate, and each pattern density, on which the relationship depends. Then, an approximate equation for approximating a CD change amount ΔCD per unit dose is obtained. Such correlation data (2) is input from the outside, and stored in the storage device 144.

The correction amount calculation unit 60 reads the correlation data (1) and (2) from the storage device 144, and calculates a dose change amount ΔD per unit temperature ΔT, depending on a pattern density, as a dose modulation rate α(x) depending on an effective temperature T. The modulation rate α(x) depending on a pattern density p is defined by the following equation (11).

$$α ( x ) = ( Δ CD / Δ T ) / {( Δ CD / Δ D )}_{ρ} = {( Δ D / Δ T )}_{ρ} \qquad ( 11 )$$

The correction amount calculation unit 60 calculates a value, as a correction amount, by multiplying the effective temperature T(i,j) by the modulation rate α(x).

In the correction step (S118), the correction unit 62 (an example of a dose correction circuit) corrects, using the effective temperature T(i,j), doses of a plurality of beams to be applied to each target mesh region. The dose D′(x) after the correction can be obtained by the following equation (12). x indicates an index of the pixel 36. (i,j) indicates an index of a processing mesh. As the pattern density ρ, a pattern density of a target pixel 36 can be used.

$${D}^{′} ( x ) = D ( x ) - T ( i , j ) \cdot α ( x ) \qquad ( 12 )$$

Then, the correction unit 62 generates, for each stripe region 32, a dose map (2) by using a calculated and corrected dose D′(x) of each pixel 36. The dose D′(x) of each pixel 36 is defined as each element of the dose map (2). Thereby, a dose distribution D′(x) after correction (after modulation) can be obtained. That is, CD dimension deviation (shift) due to a temperature increase can be corrected/returned to a design size. The generated dose map (2) is stored in the storage device 144.

In the irradiation time data generation step (S120), the irradiation time data generation unit 72 calculates, for each pixel 36, an irradiation time t of an electron beam for applying the calculated and corrected dose D′(x) to the pixel 36 concerned. The irradiation time t can be obtained by dividing the dose D′(x) by a current density J. If the dose D(x) before the correction, defined in the dose map (1), is a relative value (coefficient value of dose) to a base dose D_{base} calculated on the assumption that the base dose D_{base} is 1, a dose statistic value D₁ of each processing mesh 39 is also calculated as a relative value to the base dose D_{base}. Therefore, the effective temperature T(i,j) of each processing mesh 39 is also calculated as a relative value to the base dose D_{base}. Thus, in that case, the irradiation time t can be calculated by dividing by a value, which is obtained by multiplying the dose D′(x) by the base dose D_{base}, by a current density J. The irradiation time t of each pixel 36 is calculated as a value within the maximum irradiation time Tₜᵣ which is the maximum for irradiation with one shot of the multiple beams 20. The irradiation time t of each pixel 36 is converted to gray scale value data of 0 to 1023 gray scale levels in which the maximum irradiation time Tₜᵣ is, for example, 1023 gray scale levels (10 bits). The gray scaled irradiation time data is stored in the storage device 142.

In the data processing step (S122), the data processing unit 74 rearranges the irradiation time data in order of shot in accordance with the writing sequence, and rearranges it in order of data transmission in consideration of the arrangement order of the shift register of each group.

In the writing step (S124), under the control of the writing control unit 80, the transmission control unit 79 transmits the irradiation time data to the deflection control circuit 130 in order of shot. The deflection control circuit 130 outputs a blanking control signal to the blanking aperture array mechanism 204 in order of shot, and deflection control signals to the DAC amplifier units 132 and 134 in order of shot. The writing mechanism 150 writes a pattern on the target object 101 by using the multiple beams 20 of a dose D′(x) having been individually corrected using the effective temperature T(i,j). In other words, the writing mechanism 150 writes a pattern on the target object 101 by using a correction amount calculated using the effective temperature obtained by the effective temperature calculation method described above.

In the examples described above, the writing processing is performed one by one for the stripe region 32 for which calculation of a dose D′(x) has been completed. For example, while writing processing of a certain stripe region 32 is being carried out, in parallel to this, performed is calculation of a dose D′(x) of the stripe region 32, which is ahead by one stripe region, or a dose D′(x) of the stripe region 32, ahead by two stripe regions. In other words, the case where the writing processing and the calculation of the dose D′(x) are simultaneously performed has been described. However, it is not limited thereto. As preprocessing before starting the writing processing, calculation of an effective temperature T(i,j) and/or dose D′(x) may be performed.

As described above, according to the first embodiment, in multiple beam writing, resist heating can be corrected without accumulating the influence of temperature increase per shot per beam. Furthermore, by preparing a plurality of kernels beforehand, the volume of calculation in writing processing can be greatly reduced.

### Second Embodiment

The first embodiment has described the configuration where resist heating is corrected by dose modulation based on an effective temperature calculated using a kernel. The method for correcting resist heating is not limited thereto. According to a second embodiment, based on an effective temperature calculated using a kernel, correction is performed by resizing a figure pattern itself to be written. Hereinafter, the contents of the second embodiment are the same as those of the first embodiment except for what is particularly described below.

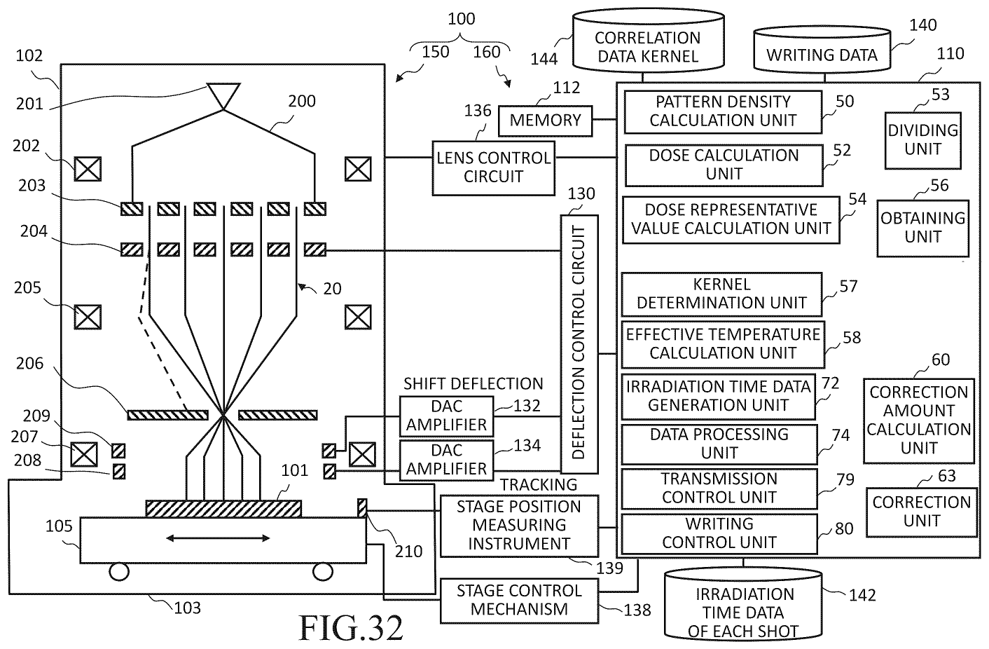

FIG. 32 is an illustration showing an example of a configuration of a writing apparatus according to the second embodiment. FIG. 32 is the same as FIG. 1 except that a correction unit 63 is arranged instead of the correction unit 62.

In FIG. 32, each of the “ . . . units” such as the pattern density calculation unit 50, the dose calculation unit 52, the dividing unit 53, the dose representative value calculation unit 54, the obtaining unit 56, the kernel determination unit 57, the effective temperature calculation unit 58, the correction amount calculation unit 60, a correction unit 63, the irradiation time data generation unit 72, the data processing unit 74, the transmission control unit 79, and the writing control unit 80 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the pattern density calculation unit 50, the dose calculation unit 52, the dividing unit 53, the dose representative value calculation unit 54, the obtaining unit 56, the kernel determination unit 57, the effective temperature calculation unit 58, the correction amount calculation unit 60, the correction unit 63, the irradiation time data generation unit 72, the data processing unit 74, the transmission control unit 79, and the writing control unit 80, and information being operated are stored in the memory 112 each time.

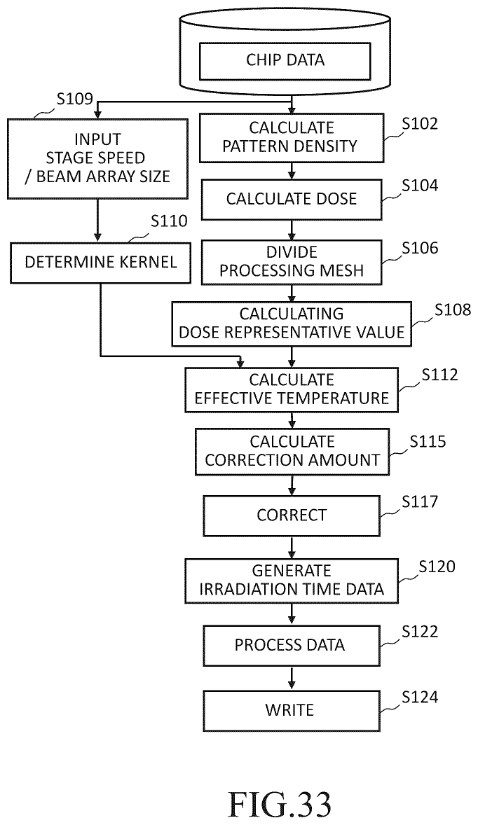

FIG. 33 is a flowchart showing an example of main steps of a writing method according to the second embodiment. FIG. 33 is the same as FIG. 11 except that a correction amount calculation step (S115) and a correction step (S117) are performed instead of the correction amount calculation step (S114) and the correction step (S118).

The contents of each step from the pattern density calculation step (S102) to the effective temperature calculation step (S112) are the same as those of the first embodiment.

In the correction amount calculation step (S115), the correction amount calculation unit 60 calculates, using the effective temperature of each of a plurality of mesh regions, a correction amount for correcting pattern data of a figure to be written in a target mesh region being one of a plurality of mesh regions of the multiple beams 20. Specifically, it operates as follows: The correction amount calculation unit 60 calculates a correction amount by using a relationship between an effective temperature T(i,j) and a dimension change amount (ΔCD/ΔT) of a pattern to be written. More concretely, the correction amount calculation unit 60 refers to the correlation data (1), stored in the storage device 144, obtained by approximating a CD change amount LCD per unit temperature ΔT. Then, a value calculated by multiplying T(i,j) by (ΔCD/ΔT) of each target mesh region is obtained as a correction amount.

In the correction step (S117), the correction unit 63 (an example of a resize processing circuit) resizes, for each processing mesh, the size of a figure pattern to be written in the processing mesh concerned, by using a correction amount calculated using a relationship between an effective temperature T(i,j) and a dimension change amount (ΔCD/ΔT) of a pattern to be written. A pattern dimension L′ (x) after the correction can be obtained by the following equation (13). x indicates an index of the pixel 36. (i,j) indicates an index of a processing mesh. As a pattern density ρ, the original pattern density of the target pixel 36 may be used.

$${L}^{′} ( x ) = L ( x ) - T ( i , j ) \cdot ( Δ CD / Δ T ) \qquad ( 13 )$$

With respect to the y-direction size L(y), a similar resizing is performed. Data of each resized figure pattern is stored in the storage device 144.

In the irradiation time data generation step (S120), the pattern density calculation unit 50 calculates, for each pixel 36 in a target stripe region 32, a pattern density p (pattern area density) by using data of a resized figure pattern. Then, a pattern density map is generated.

In the dose calculation step (S104), the dose calculation unit 52 calculates, for each pixel 36, a dose D′(x) (irradiation amount) to be applied to the pixel 36 concerned, by using a regenerated pattern density map. Then, a dose map is regenerated.

The irradiation time data generation unit 72 calculates, for each pixel 36, an irradiation time t of an electron beam for applying the calculated and resized (corrected) dose D′(x) to the pixel 36 concerned. The irradiation time t can be obtained by dividing the dose D′(x) by a current density J. The irradiation time t of each pixel 36 is calculated as a value within the maximum irradiation time Tₜᵣ which is the maximum for irradiation with one shot of the multiple beams 20. The irradiation time t of each pixel 36 is converted to gray scale value data of 0 to 1023 gray scale levels in which the maximum irradiation time Tₜᵣ is, for example, 1023 gray scale levels (10 bits). The gray scaled irradiation time data is stored in the storage device 142.

The contents of the data processing step (S122) and the writing step (S124) are the same as those of the first embodiment. In the writing step (S124), the writing mechanism 150 writes a resized pattern on the target object 101 with the multiple beams 20.

As described above, according to the second embodiment, in multiple beam writing, resist heating can be corrected by performing resize processing without accumulating the influence of temperature increase per shot per beam. Furthermore, by preparing a plurality of kernels beforehand, the volume of calculation in writing processing can be greatly reduced.

Embodiments have been explained referring to specific examples described above. However, the present invention is not limited to these specific examples. Functions of processing described in the first and the second embodiments may be executed by a computer. A program for causing a computer to implement such functions of processing may be stored in a non-transitory tangible computer-readable storage medium such as a magnetic disc device.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Further, any calculation method of an effective temperature of a multi-charged particle beam writing region, multi-charged particle beam writing apparatus, multi-charged particle beam writing method, and program (or non-transitory computer-readable storage medium storing a program) that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for calculating an effective temperature of a multi-charged particle beam writing region, comprising:
calculating a representative value of a dose of a beam to be applied to a mesh region concerned, as a dose representative value, for each of a plurality of mesh regions obtained by dividing, in a writing direction and a linearly independent first direction to the writing direction, a writing region of a target object to be irradiated with multiple charged particle beams; and
calculating, as an effective temperature of the each of the plurality of mesh regions, a representative value of an increased temperature given to the each of the plurality of mesh regions by heat due to beam irradiation, by performing convolution processing between the dose representative value and a kernel determined according to a speed of a stage with the target object thereon, and a size in the writing direction of a beam array region of the multiple charged particle beams on a surface of the target object, and outputting the effective temperature.

2. The method according to claim 1, wherein
the kernel is defined as a value of each position in a predetermined range, and
the value of the kernel at the each position indicates a representative value of a temperature during a period while the beam array region passes through a position concerned under two assumptions that point irradiation with an electric charge is applied to a center position of the kernel, and that the point irradiation is started at one end of the beam array region and completed at another end while the beam array region is continuously moving at a constant speed.

3. The method according to claim 1, wherein
a processing region of a same size as the beam array region is composed of Nₓ×N_{y} mesh regions,
the kernel is defined by an integral equation using an integral variable ω, an integral variable ξ, an integral variable u, and an integral variable v, where
the integral variable w is defined as a value obtained by converting a first quantity by setting an infinity for Nₓ, the first quantity being calculated by dividing a reference number i, which indicates a mesh region in the writing direction in a processing region of a same size as the beam array region, by a number of mesh regions, Nₓ, in the writing direction in the processing region overlapping with the beam array region, and multiplying a divided value by a size Lₓ of the beam array region in the writing direction,
the integral variable ξ is defined as a value obtained by converting a second quantity by setting an infinity for N_{y}, the second quantity being calculated by dividing a reference number j, which indicates a mesh region in the first direction in the processing region of the same size as the beam array region, by a number of mesh regions, N_{y}, in the first direction in the processing region overlapping with the beam array region, and multiplying a divided value by a size L_{y} of the beam array region in the first direction,
the integral variable u is defined as a value obtained by converting a third quantity by setting an infinity for Nₓ, the third quantity being calculated by dividing a beam irradiation number m, which is m=k−Nₓ+1, k−Nₓ, and . . . k and indicates a number of beam irradiation sequentially performed Nₓ times until the processing region of a size of Nₓ×N_{y} mesh regions has passed through a target mesh (k,l), by the number of mesh regions, Nₓ, and multiplying a divided value by a size Lₓ of the beam array region in the writing direction, and
the integral variable v is defined as a value obtained by converting a fourth quantity by setting an infinity for Nₓ, the fourth quantity being calculated by dividing a beam irradiation number n, which is a number of beam irradiation sequentially performed such as m-th, (m−1)th, (m−2)th, . . . , by the number of mesh regions, Nₓ, and multiplying a divided value by a size Lₓ of the beam array region in the writing direction.

4. A multi-charged particle beam writing method comprising:
calculating, using an effective temperature obtained by the method according to claim 1 of each of the plurality of mesh regions, a correction amount to correct one of a dose of a plurality of beams, to be applied to a target mesh region being one of the plurality of mesh regions, of multiple charged particle beams, and pattern data of a figure to be written in the target mesh region; and
writing, with the multiple charged particle beams, a pattern on a target object by using the correction amount.

5. A non-transitory computer-readable storage medium storing a program for causing a computer to execute processing comprising:
calculating a representative value of a dose of a beam to be applied to a mesh region concerned, as a dose representative value, for each of a plurality of mesh regions obtained by dividing, in a writing direction and a linearly independent direction to the writing direction, a writing region of a target object to be irradiated with multiple charged particle beams; and
calculating, as an effective temperature of the each of the plurality of mesh regions, a representative value of an increased temperature given to the each of the plurality of mesh regions by heat due to beam irradiation, by performing convolution processing between the dose representative value and a kernel determined according to a speed of a stage with the target object thereon, and a size in the writing direction of the beam array region of the multiple charged particle beams on a surface of the target object, and outputting the effective temperature.

6. A non-transitory computer-readable storage medium storing a program for causing a computer to execute processing, comprising:
calculating the dose representative value and calculating the effective temperature value according to claim 5;
calculating, using an effective temperature of each of the plurality of mesh regions, a correction amount to correct one of a dose of a plurality of beams, to be applied to a target mesh region being one of the plurality of mesh regions, of multiple charged particle beams, and pattern data of a figure to be written in the target mesh region; and
writing, with the multiple charged particle beams, a pattern on a target object by using the correction amount.

7. A multi-charged particle beam writing apparatus comprising:
a dose representative value calculation circuit configured to calculate a representative value of a dose of a beam to be applied to a mesh region concerned, as a dose representative value, for each of a plurality of mesh regions obtained by dividing, in a writing direction and a linearly independent direction to the writing direction, a writing region of a target object to be irradiated with multiple charged particle beams;
an effective temperature calculation circuit configured to calculate, as an effective temperature of the each of the plurality of mesh regions, a representative value of an increased temperature given to the each of the plurality of mesh regions by heat due to beam irradiation, by performing convolution processing between the dose representative value and a kernel determined according to a speed of a stage with the target object thereon, and a size in the writing direction of the beam array region of the multiple charged particle beams on a surface of the target object;
a correction amount calculation circuit configured to calculate, using an effective temperature of the each of the plurality of mesh regions, a correction amount to correct one of a dose of a plurality of beams, to be applied to a target mesh region being one of the plurality of mesh regions, of the multiple charged particle beams, and pattern data of a figure to be written in the target mesh region; and
a writing mechanism configured to write, with the multiple charged particle beams, a pattern on the target object by using the correction amount.
